(19) United States
(12) Patent Application Publication
(10) Pub. No.: US 2020/0373433 A1
(43) Pub. Date: Nov. 26, 2020

(54) SEMICONDUCTOR DEVICE

(71) Applicant: SEMICONDUCTOR ENERGY LABORATORY CO., LTD., ATSUGI-SHI, KANAGAWA-KEN (JP)

(72) Inventors: Shunpei YAMAZAKI, Setagaya, Tokyo (JP); Toshimitsu OBONAI, Shimotsuke, Tochigi (JP); Yasuharu HOSAKA, Tochigi, Tochigi (JP); Mitsuo MASHIYAMA, Oyama, Tochigi (JP); Toshikatsu KUNII, Tochigi, Tochigi (JP); Hironobu TAKAHASHI, Oyama, Tochigi (JP); Kenichi OKAZAKI, Tochigi, Tochigi (JP)

(73) Assignee: SEMICONDUCTOR ENERGY LABORATORY CO., LTD., ATSUGI-SHI, KANAGAWA-KEN (JP)

(21) Appl. No.: 16/645,522

(22) PCT Filed: Oct. 12, 2018
(86) PCT No.: PCT/IB2018/057908

§ 371 Date: Mar. 9, 2020

(30) Foreign Application Priority Data
Oct. 20, 2017 (JP) 2017-203333

(51) Int. Cl. H01L 29/786; H01L 29/66

(52) U.S. Cl. CPC H01L 29/78606; H01L 29/7869; H01L 21/02178; H01L 29/78603; H01L 29/66969

(57) ABSTRACT

A semiconductor device with favorable electrical characteristics is provided. A semiconductor device with stable electrical characteristics is provided. The semiconductor device is configured to include a first insulating layer, a second insulating layer, a third insulating layer, a first conductive layer, and a semiconductor layer. The semiconductor layer is positioned over the first insulating layer. The first conductive layer is positioned over the semiconductor layer. The second insulating layer covers a side surface and a bottom surface of the first conductive layer. The third insulating layer is in contact with a top surface of the first insulating layer and part of a top surface of the semiconductor layer and covers a side surface of the second insulating layer. The semiconductor layer contains a metal oxide, the first insulating layer and the second insulating layer each contain an oxide, and the third insulating layer contains a metal nitride.

### TECHNICAL FIELD

One embodiment of the present invention relates to a semiconductor device. One embodiment of the present invention relates to a method for manufacturing a semiconductor device.

Note that one embodiment of the present invention is not limited to the above technical field. Examples of the technical field of one embodiment of the present invention disclosed in this specification and the like include a semiconductor device, a display device, a light-emitting device, a power storage device, a memory device, an electronic device, a lighting device, an input device, an input/output device, a driving method thereof, and a manufacturing method thereof. A semiconductor device generally means a device that can function by utilizing semiconductor characteristics.

### BACKGROUND ART

As a semiconductor material that can be used in a transistor, an oxide semiconductor using a metal oxide has been attracting attention. For example, Patent Document 1 discloses a semiconductor device which makes field-effect mobility (simply referred to as mobility or μFE in some cases) to be increased by stacking a plurality of oxide semiconductor layers, containing indium and gallium in an oxide semiconductor layer serving as a channel in the plurality of oxide semiconductor layers, and making the proportion of indium higher than the proportion of gallium.

A metal oxide that can be used for a semiconductor layer can be formed by a sputtering method or the like, and thus can be used for a semiconductor layer of a transistor included in a large display device. In addition, capital investment can be reduced because production facility for transistors using polycrystalline silicon or amorphous silicon, which is partly retrofitted, can be utilized. In addition, a transistor using a metal oxide has field-effect mobility higher than that in the case where amorphous silicon is used; thus, a high-performance display device integrated with driver circuits, for example, can be obtained.

Patent Document 2 discloses a thin film transistor in which a source region and a drain region use an oxide semiconductor film including a low-resistance region containing at least one kind in a group consisting of aluminum, boron, gallium, indium, titanium, silicon, germanium, tin, and lead as a dopant.

### REFERENCES

### Patent Documents

[Patent Document 1] Japanese Published Patent Application No. 2014-7399

[Patent Document 2] Japanese Published Patent Application No. 2011-228622

### SUMMARY OF THE INVENTION

### Problems to be Solved by the Invention

One object of one embodiment of the present invention is to provide a semiconductor device which has favorable electrical characteristics. Alternatively, an object is to provide a semiconductor device with stable electrical characteristics.

Note that the descriptions of these objects do not disturb the existence of other objects. Note that in one embodiment of the present invention, there is no need to achieve all the objects. Note that objects other than them can be derived from the descriptions of the specification, the drawings, the claims, and the like.

### Means for Solving the Problems

One embodiment of the present invention is a semiconductor device including a first insulating layer, a second insulating layer, a third insulating layer, a first conductive layer, and a semiconductor layer. The semiconductor layer is positioned over the first insulating layer. The first conductive layer is positioned over the semiconductor layer. The second insulating layer covers a side surface and a bottom surface of the first conductive layer. The third insulating layer is in contact with a top surface of the first insulating layer and part of a top surface of the semiconductor layer and covers a side surface of the second insulating layer. The semiconductor layer includes a metal oxide, the first insulating layer and the second insulating layer contain an oxide, and the third insulating layer contains a metal nitride.

Furthermore, one embodiment of the present invention is a semiconductor device including a first insulating layer, a second insulating layer, a third insulating layer, a fourth insulating layer, a semiconductor layer, and a first conductive layer. The semiconductor layer is provided over and in contact with the first insulating layer and includes a first region and a second region. The second insulating layer is provided over the first insulating layer and the second region and has a first opening overlapping with the first region. The first conductive layer is positioned inside the first opening and includes a portion overlapping with the first region. The third insulating layer is positioned inside the first opening, covers a side surface and a bottom surface of the first conductive layer, and is in contact with a top surface of the first region of the semiconductor layer. The fourth insulating layer is in contact with a top surface of the first insulating layer, a side surface of the semiconductor layer, and a top surface of the second region, and includes a portion that is inside the first opening and between the second insulating layer and the third insulating layer. The semiconductor layer contains a metal oxide, the first insulating layer and the third insulating layer contain an oxide, and the fourth insulating layer contains a metal nitride.

In the above, the fourth insulating layer preferably contains aluminum.

Furthermore, in the above, it is preferable to include a fifth insulating layer covering top surfaces of the second insulating layer, the first conductive layer, and the third insulating layer. In this case, the fifth insulating layer preferably contains at least one of aluminum and hafnium, and oxygen.

Furthermore, in the above, it is preferable to include a second conductive layer over the fifth insulating layer. In this case, it is preferable that the fifth insulating layer and the second insulating layer have a second opening which reaches the second region and that the second conductive layer be in contact with the second region through the second opening.

Furthermore, in the above, it is preferable to include a sixth insulating layer below the first insulating layer. At this time, the sixth insulating layer preferably contains at least one of aluminum and hafnium, and oxygen.

In the above, it is preferable that the first insulating layer have a third opening which reaches the sixth insulating layer and that the fourth insulating layer be in contact with the sixth insulating layer through the third opening.

Furthermore, in the above, it is preferable to include a third conductive layer that is below the sixth insulating layer and overlaps with the first region.

### Effect of the Invention

According to one embodiment of the present invention, a semiconductor device with favorable electrical characteristics can be provided. Alternatively, a semiconductor device with stable electrical characteristics can be provided. Alternatively, a highly reliable semiconductor device can be provided.

Note that the descriptions of the effects do not disturb the existence of other effects. Note that one embodiment of the present invention does not necessarily have all the effects. Effects other than them can be derived from the descriptions of the specification, the drawings, the claims, and the like.

### BRIEF DESCRIPTION OF THE DRAWINGS

FIG. 1 A structure example of a semiconductor device.

FIG. 2 A structure example of a semiconductor device.

FIG. 3 A structure example of a semiconductor device.

FIG. 4 A structure example of a semiconductor device.

FIG. 5 Diagrams illustrating an example of a method for manufacturing a semiconductor device.

FIG. 6 Diagrams illustrating an example of a method for manufacturing a semiconductor device.

FIG. 7 Diagrams illustrating an example of a method for manufacturing a semiconductor device.

FIG. 8 Diagrams illustrating an example of a method for manufacturing a semiconductor device.

FIG. 9 Top views of display devices.

FIG. 10 A block diagram and circuit diagrams of a display device.

FIG. 11 A block diagram of a display device.

FIG. 12 A block diagram of a memory device.

FIG. 13 A block diagram and a circuit diagram of a memory device.

FIG. 14 Diagrams illustrating electronic devices.

FIG. 15 TDS analysis results.

FIG. 16 TDS analysis results.

FIG. 17 TDS analysis results.

FIG. 18 Sheet resistance measurement results.

FIG. 19 SIMS analysis results.

FIG. 20 SIMS analysis results.

FIG. 21 SIMS analysis results.

### MODE FOR CARRYING OUT THE INVENTION

Hereinafter, embodiments will be described with reference to drawings. Note that the embodiments can be implemented with many different modes, and it will be readily appreciated by those skilled in the art that modes and details can be changed in various ways without departing from the spirit and scope of the present invention. Thus, the present invention should not be interpreted as being limited to the following description of the embodiments.

Furthermore, in each drawing described in this specification, the size, the layer thickness, or the region of each component is exaggerated for clarity in some cases.

Note that ordinal numbers such as “first”, “second”, and “third” used in this specification are used in order to avoid confusion among components, and the terms do not limit the components numerically.

In this specification, terms for describing arrangement, such as “over” and “under”, are used for convenience in describing a positional relationship between components with reference to drawings. The positional relation between components is changed as appropriate in accordance with a direction in which components are described. Thus, terms for the description are not limited to those used in this specification, and the description can be changed appropriately depending on the situation.

In this specification and the like, functions of a source and a drain of a transistor are sometimes switched from each other depending on the polarity of the transistor, the case where the direction of current flow is changed in circuit operation, or the like. Thus, the terms of source and drain are interchangeable for use.

Furthermore, in this specification and the like, “electrically connected” includes the case where connection is made through an “object having any electric function”. Here, there is no particular limitation on the “object having any electric function” as long as electric signals can be transmitted and received between the connected components. Examples of the “object having any electric function” include a switching element such as a transistor, a resistor, an inductor, a capacitor, and other elements having a variety of functions as well as an electrode and a wiring.

Moreover, in this specification and the like, the term “film” and the term “layer” can be interchanged with each other. For example, in some cases, the terms “conductive layer” and “insulating layer” can be changed into “conductive film” and “insulating film”, respectively.

Unless otherwise specified, an off-state current in this specification and the like refers to a drain current of a transistor in an off state (also referred to as a non-conducting state or a cutoff state). Unless otherwise specified, an off state refers to, in an n-channel transistor, a state where the voltage V_{gs} between its gate and source is lower than the threshold voltage Vₜₕ (in a p-channel transistor, higher than Vₜₕ).

### Embodiment 1

In this embodiment, a semiconductor device of one embodiment of the present invention is described. Hereinafter, a transistor which is one embodiment of the semiconductor device will be described.

An embodiment of the present invention is a transistor including, over an insulating layer containing an oxide, a semiconductor layer where a channel is formed, a gate insulating layer over the semiconductor layer, and a gate electrode over the gate insulating layer. The semiconductor layer contains a metal oxide showing semiconductor characteristics (hereinafter also referred to as an oxide semiconductor).

The semiconductor layer includes a channel formation region where a channel is to be formed and a pair of low-resistance regions functioning as a source region and a drain region. The channel formation region is a region which is included in the semiconductor layer and overlaps with the gate electrode.

An insulating layer containing a metal nitride is provided over and in contact with the low-resistance regions. When the insulating layer containing a metal nitride is provided in contact with the semiconductor layer, an effect of increasing the conductivity of the low-resistance regions is caused. Furthermore, it is preferable that heat treatment be performed in a state where the insulating layer containing a metal nitride is provided in contact with the semiconductor layer because resistance can be further reduced.

It is particularly preferable that the metal nitride contain aluminum. For example, an aluminum nitride film formed by a reactive sputtering method using aluminum as a sputtering target and a gas containing nitrogen as a deposition gas can have both an extremely high insulating property and an extremely high blocking property against hydrogen and oxygen when the ratio of the nitrogen-gas flow rate to the total flow rate of the deposition gas is properly controlled. Therefore, when such an insulating film containing a metal nitride is provided in contact with the semiconductor layer, the resistance of the semiconductor layer can be reduced, and the release of oxygen from the semiconductor layer and the diffusion of hydrogen into the semiconductor layer can be favorably prevented.

In the case where aluminum nitride is used as the metal nitride, the thickness of the insulating layer containing aluminum nitride is preferably 5 nm or more. A film with such a small thickness can also have both a high blocking property against hydrogen and oxygen and a function of reducing the resistance of the semiconductor layer. Note that there is no upper limit of the thickness of the insulating layer; however, the thickness is preferably 500 nm or less, further preferably 200 nm or less, still further preferably 50 nm or less in consideration of productivity.

Furthermore, an interlayer insulating layer is provided over the insulating layer containing a metal nitride. Here, the gate electrode and the gate insulating layer are preferably provided so as to be embedded in an opening formed in the interlayer insulating layer. Specifically, the gate insulating layer is preferably provided so as to cover a side surface and a bottom surface of the gate electrode inside the opening. Moreover, it is preferable that the insulating layer containing a metal nitride be provided between the inner wall of the interlayer insulating layer and the outer surface of the gate insulating layer. When the interlayer insulating layer and the gate insulating layer are not in contact with each other in this manner, hydrogen contained in the interlayer insulating layer can be prevented from being diffused into the semiconductor layer through the gate insulating layer. Furthermore, oxygen contained in the semiconductor layer and the gate insulating layer can be prevented from being diffused to the interlayer insulating layer side.

It is preferable that the interlayer insulating layer, the insulating layer containing a metal nitride, the gate insulating layer, and the gate electrode have planarized top surfaces. Furthermore, it is preferable that an insulating layer through which oxygen and hydrogen are less likely to be diffused (also referred to as a first barrier layer) be formed on the planarized surfaces to be in contact with the interlayer insulating layer, the insulating layer containing a metal nitride, the gate insulating layer, and the gate electrode. Thus, it is possible to favorably prevent the diffusion of hydrogen from a portion above the gate electrode and the gate insulating layer and the release of oxygen toward the above portion.

It is preferable that an insulating layer (also referred to as a second barrier layer) through which oxygen and hydrogen are less likely to be diffused be provided below the insulating layer containing an oxide which includes a surface where the semiconductor layer is provided. Furthermore, it is preferable that an opening reaching the second barrier layer be formed in the insulating layer containing an oxide to surround one or more transistors and that the second barrier layer and the insulating layer containing a metal nitride be in contact with each other in the opening. By this, the transistor can have such a structure that the semiconductor layer, the gate insulating layer, and the gate electrode are surrounded by the insulating layer containing a metal nitride, the first barrier layer, and the second barrier layer. Thus, it is possible to favorably prevent the diffusion of hydrogen to the semiconductor layer and the release of oxygen from the semiconductor layer, whereby a transistor with extremely high reliability can be achieved.

The transistor of one embodiment of the present invention can be applied to a variety of circuits and devices. For example, the transistor can be favorably used for a variety of circuits such as an arithmetic circuit, a memory circuit, a driver circuit, and an interface circuit in an IC chip mounted on an electronic device or the like, display devices including a liquid crystal element, an organic EL element, or the like, driver circuits in various sensor devices, or the like.

A more specific example of the transistor of one embodiment of the present invention will be described below with reference to drawings.

### Structure Example 1

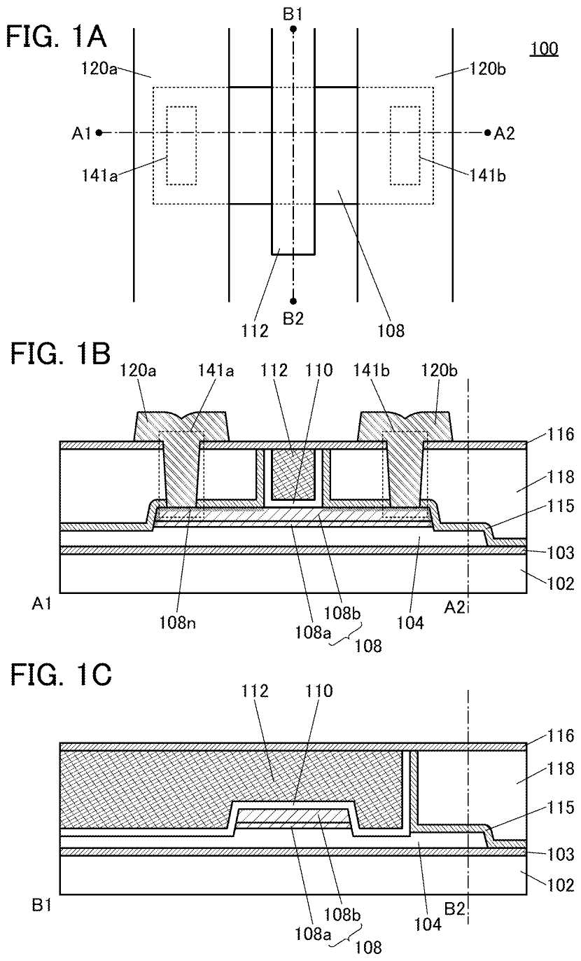

FIG. 1(A) is a top view of a transistor 100, FIG. 1(B) corresponds to a cross-sectional view taken along dashed-dotted line A1-A2 in FIG. 1(A), and FIG. 1(C) corresponds to a cross-sectional view taken along dashed-dotted line B1-B2 in FIG. 1(A). Note that in FIG. 1(A), some components of the transistor 100 (a gate insulating layer and the like) are not illustrated. Furthermore, in some cases, the direction of the dashed-dotted line A1-A2 may be referred to as a channel length direction, and the direction of the dashed-dotted line B1-B2 may be referred to as a channel width direction. Note that some components are not illustrated in some cases in top views of transistors in the following drawings, as in FIG. 1(A).

The transistor 100 is provided over a substrate 102 and includes an insulating layer 103, an insulating layer 104, a semiconductor layer 108, an insulating layer 110, a conductive layer 112, an insulating layer 115, an insulating layer 118, an insulating layer 116, and the like.

The insulating layer 103 and the insulating layer 104 are provided over the substrate 102. The island-shaped semiconductor layer 108 is provided in contact with a tope surface of the insulating layer 104. The insulating layer 115 and the insulating layer 118 are stacked over the insulating layer 104 and the semiconductor layer 108. The insulating layer 118 has an opening in a region overlapping with the semiconductor layer 108. The insulating layer 115 is provided to cover an inner wall of an opening portion in the insulating layer 118. In the opening of the insulating layer 118, the insulating layer 110 is provided in contact with a side surface of the insulating layer 115 and a top surface of the semiconductor layer 108, and the conductive layer 112 is provided over the insulating layer 110. The insulating layer 110 is provided in contact with a side surface and a bottom surface of the conductive layer 112.

Portions above the insulating layer 118, the insulating layer 115, the insulating layer 110, and the conductive layer 112 are subjected to planarization, and the insulating layer 116 is provided thereover.

Part of the conductive layer 112 functions as a gate electrode. Part of the insulating layer 110 functions as a gate insulating layer. The transistor 100 is what is called a top-gate transistor, in which the gate electrode is provided over the semiconductor layer 108.

The semiconductor layer 108 preferably contains a metal oxide.

For example, the semiconductor layer 108 preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc. In particular, the element M is preferably aluminum, gallium, yttrium, or tin.

It is particularly preferable to use an oxide containing indium, gallium, and zinc for the semiconductor layer 108.

Here is shown an example where the semiconductor layer 108 has a stacked-layer structure in which a semiconductor layer 108a and a semiconductor layer 108b are stacked in this order from the insulating layer 104 side. For each of the semiconductor layers 108a and 108b, materials having different compositions, materials having different crystallinity, or materials having different impurity concentrations may be selected.

Low-resistance regions 108n are provided in the vicinity of a surface of the semiconductor layer 108 which is in contact with the insulating layer 115.

A region of the semiconductor layer 108 overlapping with the conductive layer 112 functions as a channel formation region of the transistor 100. Meanwhile, the low-resistance region 108n functions as a source region or a drain region of the transistor 100.

For the insulating layer 115, an insulating film containing a metal nitride can be used. The insulating layer 115 preferably contains at least one of metal elements such as aluminum, titanium, tantalum, tungsten, chromium, and ruthenium and nitrogen. In particular, a film containing aluminum and nitrogen is preferable because of its high insulating property.

In the case of using an aluminum nitride film as the insulating layer 115, it is preferable to use a film that satisfies the composition formula AlNₓ (x is a real number greater than 0 and less than or equal to 2, preferably greater than or equal to 0.5 and less than or equal to 1.5). In that case, a film having an excellent insulating property and high thermal conductivity can be obtained, and thus dissipation of heat generated in driving the transistor 100 can be increased.

Alternatively, an aluminum titanium nitride film, a titanium nitride film, or the like can be used as the insulating layer 115.

The regions 108n are parts of the semiconductor layer 108 and have lower resistance than the channel formation region.

Here, in the case where a metal oxide film containing indium is used as the semiconductor layer 108, a region where metal indium is deposited or a region having a high indium concentration is sometimes formed in the vicinity of the interface of the regions 108n on the insulating layer 115 side. Such regions can be observed by an analysis method such as an X-ray photoelectron spectroscopy (XPS) in some cases, for example.

Furthermore, the region 108n can be regarded as a region having higher carrier density than the channel formation region, a region having a higher oxygen defect density than the channel formation region, or an n-type region.

Furthermore, as each of the insulating layer 104 and the insulating layer 110 that are in contact with the channel formation region of the semiconductor layer 108, an oxide film is preferably used. For example, an oxide film such as a silicon oxide film, a silicon oxynitride film, or an aluminum oxide film can be used. Accordingly, heat treatment performed in the manufacturing process of the transistor 100 enables oxygen released from the insulating layer 104 or the insulating layer 110 to be supplied to the channel formation region of the semiconductor layer 108, thereby reducing oxygen vacancies in the semiconductor layer 108.

As each of the insulating layer 103 provided below the insulating layer 104 (on the substrate 102 side) and the insulating layer 116 covering the insulating layer 118 and the like, an insulating film through which oxygen and hydrogen are less likely to diffuse is preferably used. It is particularly preferable to use a metal oxide film such as an aluminum oxide film, a hafnium oxide film, or a hafnium aluminate film.

An aluminum oxide film, a hafnium oxide film, a hafnium aluminate film, or the like has an extremely high barrier property even when its thickness is small. Accordingly, the thickness can be more than or equal to 0.5 nm and less than or equal to 50 nm, preferably more than or equal to 1 nm and less than or equal to 40 nm, further preferably more than or equal to 2 nm and less than or equal to 30 nm. In particular, an aluminum oxide film has a high barrier property against hydrogen or the like and thus gives a sufficient effect even when having an extremely small thickness (e.g., more than or equal to 0.5 nm and less than or equal to 1.5 nm).

Furthermore, the insulating layer 103 or the insulating layer 116 is preferably formed by a deposition method such as a sputtering method or an atomic layer deposition (ALD) method. Specifically, the ALD method enables deposition of an extremely dense film with high step coverage, whereby a film with a high barrier property can be formed.

The right sides in FIGS. 1(B) and 1(C) each illustrate a cross section of a peripheral portion of the semiconductor device. In the peripheral portion, an opening is formed by removing part of the insulating layer 104 by etching. In the opening, the insulating layer 115 is in contact with the insulating layer 103.

For example, when a region where the insulating layer 115 is in contact with the insulating layer 103 is provided so as to surround a block including one or more of the transistor 100 (the block is provided for each circuit or chip, for example), the transistor 100 in the block can be sealed by the insulating layer 103, the insulating layer 116, and the insulating layer 115. Accordingly, the diffusion of hydrogen from the outside into the semiconductor layer 108 of the transistor 100 and the release of oxygen in the semiconductor layer 108 to the outside can be effectively suppressed.

In addition, although the insulating layer 118 contains hydrogen in some cases, the insulating layers 104 and 110 each containing an oxide film in contact with the semiconductor layer 108 each have such a structure as not to be in contact with the insulating layer 118 by the insulating layer 115. Thus, even when the insulating layer 118 contains hydrogen, it is possible to effectively prevent the diffusion of hydrogen, which is caused by heat or the like generated in the manufacturing process of the transistor 100, to the semiconductor layer 108 through the insulating layer 104 and the insulating layer 110.

Here, oxygen vacancies that might be formed in the semiconductor layer 108 and the semiconductor layer 108 will be described.

Oxygen vacancies formed in the semiconductor layer 108 adversely affect the transistor characteristics and therefore cause a problem. For example, when an oxygen vacancy is formed in the semiconductor layer 108, the oxygen vacancy might be bonded with hydrogen to serve as a carrier supply source. The carrier supply source generated in the semiconductor layer 108 causes a variation in the electrical characteristics, typically, a shift in the threshold voltage, of the transistor 100. Therefore, it is preferable that the amount of oxygen vacancies in the semiconductor layer 108 be as small as possible.

In view of this, in one embodiment of the present invention, the insulating films near the semiconductor layer 108, specifically, the insulating layer 110 positioned above the semiconductor layer 108 and the insulating layer 104 positioned below the semiconductor layer 108 each include an oxide film. When oxygen is moved from the insulating layer 104 and the insulating layer 110 to the semiconductor layer 108 by heat during the manufacturing process or the like, the amount of oxygen vacancies in the semiconductor layer 108 can be reduced.

Furthermore, the semiconductor layer 108 preferably includes a region where the atomic proportion of In is higher than that of M. A higher atomic proportion of In results in higher field-effect mobility of the transistor.

Here, in the case of a metal oxide containing In, Ga, and Zn, bonding strength between In and oxygen is weaker than bonding strength between Ga and oxygen; hence, with a higher atomic proportion of In, oxygen vacancies are likely to be generated in the metal oxide film. There is a similar tendency when a metal element, instead of Ga, represented by M as the above is used. A large amount of oxygen vacancies in the metal oxide film leads to deterioration of electrical characteristics and reduction in reliability of a transistor.

In contrast, in one embodiment of the present invention, an extremely large amount of oxygen can be supplied to the semiconductor layer 108 containing a metal oxide; thus, the semiconductor layer 108 can be formed using a metal oxide material with a high atomic proportion of In. Accordingly, it is possible to achieve a transistor with extremely high field-effect mobility, stable electrical characteristics, and high reliability.

For example, a metal oxide in which the atomic proportion of In is 1.5 times or more, 2 times or more, 3 times or more, 3.5 times or more, or 4 times or more that of M can be favorably used.

In particular, it is preferable that the atomic ratio of In to M and Zn in the semiconductor layer 108 be In:M:Zn=5:1:6 or in its neighborhood (including the case where when In=5, M is more than or equal to 0.5 and less than or equal to 1.5 and Zn is more than or equal to 5 and less than or equal to 7). Alternatively, the atomic ratio of In to M and Zn is preferably In:M:Zn=4:2:3 or in its neighborhood thereof. Furthermore, as the composition of the semiconductor layer 108, the atomic proportions of In, M, and Zn in the semiconductor layer 108 may be approximately equal to each other. That is, a material having an atomic ratio of In to M and Zn being In:M:Zn=1:1:1 or in its neighborhood thereof may be included.

For example, with use of the transistor with high field-effect mobility in a gate driver that generates a gate signal, the display device with a small frame width (also referred to as a narrow frame) can be provided. Furthermore, with use of the above transistor with high field-effect mobility in a source driver (particularly in a demultiplexer connected to an output terminal of a shift register included in the source driver), a display device to which fewer wirings are connected can be provided.

Note that even when the semiconductor layer 108 includes a region where the atomic proportion of In is higher than that of M, the field-effect mobility may sometimes be low if the semiconductor layer 108 has high crystallinity. The crystallinity of the semiconductor layer 108 can be analyzed by using X-ray diffraction (XRD) or a transmission electron microscope (TEM), for example.

Impurities such as hydrogen or moisture entering the semiconductor layer 108 adversely affect the transistor characteristics and therefore cause a problem. Thus, it is preferable that the amount of impurities such as hydrogen or moisture in the semiconductor layer 108 be as small as possible. It is preferable to use a metal oxide film in which the impurity concentration is low and the density of defect states is low, in which case the transistor having excellent electrical characteristics can be fabricated. By reducing the impurity concentration and the density of defect states (reduce the number of oxygen vacancies), the carrier density in the film can be decreased. A transistor using such a metal oxide film for a semiconductor layer rarely has a negative threshold voltage (is rarely normally on). Furthermore, the transistor using such a metal oxide film can have extremely low off-state current.

The semiconductor layer 108 may have a stacked structure including two or more layers.

For example, the semiconductor layer 108 can be a stack including two or more metal oxide films with different compositions. For instance, in the case of using an In-M-Zn oxide, the semiconductor layer 108 is preferably a stack including at least two films each deposited using a sputtering target with an atomic ratio of In to M and Zn represented by In:M:Zn=5:1:6, 4:2:3, 1:1:1, 2:2:1, 1:3:4, 1:3:2 or in its neighborhood thereof.

Alternatively, the semiconductor layer 108 can be a stack including two or more metal oxide films with different crystallinities. In that case, the stacked semiconductor layer 108 is preferably successively formed without exposure to the atmospheric air using the same oxide target under different deposition conditions.

For example, the oxygen flow rate ratio at the time of forming the first metal oxide film (the semiconductor layer 108a) is set lower than that at the time of forming the second metal oxide film (the semiconductor layer 108b) in a later step. Alternatively, a condition without oxygen flowing is employed at the time of forming the first metal oxide film. In such a manner, oxygen can be effectively supplied at the time of forming the second metal oxide film. The first metal oxide film can have lower crystallinity and higher electrical conductivity than the second metal oxide film. Meanwhile, when the second metal oxide film as the upper film has higher crystallinity than the first metal oxide film, damage caused at the time of processing the semiconductor layer 108 or forming the gate insulating layer 110 can be inhibited.

Specifically, the oxygen flow rate ratio at the time of forming the first metal oxide film is higher than or equal to 0% and lower than 50%, preferably higher than or equal to 0% and lower than or equal to 30%, further preferably higher than or equal to 0% and lower than or equal to 20%, typically 10%. The oxygen flow rate ratio at the time of forming the second metal oxide film is higher than or equal to 50% and lower than or equal to 100%, preferably higher than or equal to 60% and lower than or equal to 100%, further preferably higher than or equal to 80% and lower than or equal to 100%, still further preferably higher than or equal to 90% and lower than or equal to 100%, typically 100%. Although the conditions at the time of the film deposition, such as pressure, temperature, and power, may vary between the first metal oxide film and the second metal oxide film, it is preferable to employ the same conditions other than the oxygen flow rate ratio, in which case the time required for the film formation steps can be shortened.

With such a structure, the transistor 100 can have excellent electrical characteristics and high reliability.

The above is the description of Structure Example 1.

A structural example of a transistor whose structure is partly different from that of Structural Example 1 described above will be described below. Note that description of the same portions as those in Structural Example 1 described above is skipped in some cases. Furthermore, in the drawings that are referred to later, the same hatching pattern is applied to portions having functions similar to those in the above structural example, and the portions are not denoted by reference numerals in some cases.

[Structure Example 2]

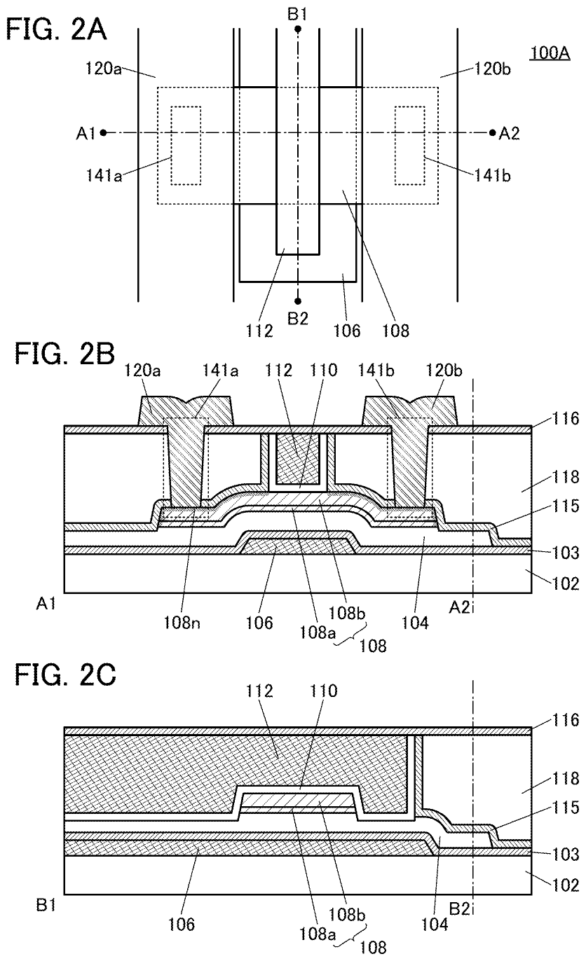

FIG. 2(A) is a top view of a transistor 100A, FIG. 2(B) is a cross-sectional view of the transistor 100A in the channel length direction, and FIG. 2(C) is a cross-sectional view of the transistor 100A in the channel width direction.

The transistor 100A is different from Structure Example 1 mainly in including a conductive layer 106 between the substrate 102 and the insulating layer 103. The conductive layer 106 includes a portion overlapping with the semiconductor layer 108 and the conductive layer 112 with the insulating layers 103 and 104 positioned therebetween.

In the transistor 100A, the conductive layer 106 has a function of a first gate electrode (also referred to as a bottom gate electrode), and the conductive layer 112 has a function of a second gate electrode (also referred to as a top gate electrode). Part of the insulating layers 103 and 104 function as a first gate insulating layer, and part of the insulating layer 110 functions as a second gate insulating layer.

A portion of the semiconductor layer 108 that overlaps with at least one of the conductive layer 112 and the conductive layer 106 functions as a channel formation region. Note that for easy explanation, a portion of the semiconductor layer 108 that overlaps with the conductive layer 112 will be sometimes referred to as a channel formation region in the following description; however, a channel can be actually formed in a portion (including part of the low-resistance region 108n) not overlapping with the conductive layer 112 and overlapping with the conductive layer 106.

The conductive layer 106 can be formed using a material similar to that for the conductive layer 112, a conductive layer 120a, or a conductive layer 120b. It is particularly suitable to use a material containing copper for formation of the conductive layer 106 because the resistance can be reduced.

As illustrated in FIGS. 2(A) and 2(C), the conductive layer 112 and the conductive layer 106 preferably extend beyond an end portion of the semiconductor layer 108 in the channel width direction. In that case, as shown in FIG. 2(C), the semiconductor layer 108 is entirely covered with the conductive layer 112 and the conductive layer 106 in the channel width direction with the insulating layer 110 and the insulating layers 103 and 104 therebetween.

With such a structure, the semiconductor layer 108 can be electrically surrounded by electric fields generated by a pair of gate electrodes. At this time, it is preferable that the same potential be supplied to the conductive layer 106 and the conductive layer 112. In that case, electric fields for inducing a channel can be effectively applied to the semiconductor layer 108, whereby the on-state current of the transistor 100A can be increased. Thus, the transistor 100A can also be miniaturized.

Alternatively, a constant potential may be supplied to one of the conductive layer 112 and the conductive layer 106, thereby supplying a signal for driving the transistor 100A. In this case, the potential supplied to one of the gate electrodes enables control of the threshold voltage at the time of driving the transistor 100A with the other gate electrode.

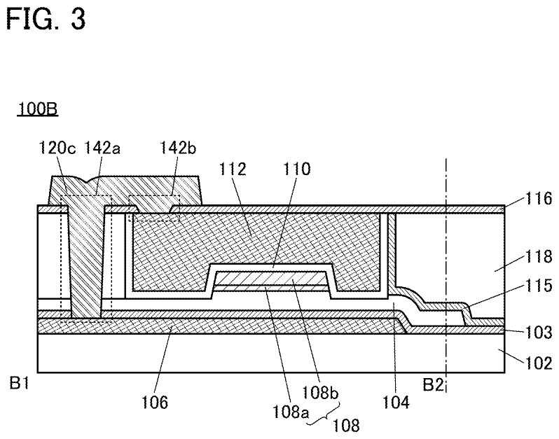

Alternatively, as in a transistor 100B illustrated in FIG. 3, the conductive layer 106 may be electrically connected to the conductive layer 112. FIG. 3 illustrates an example in which the conductive layer 120c formed in the same step as the conductive layer 120a or the like is provided over the insulating layer 116. The conductive layer 120c is electrically connected to the conductive layer 106 through an opening 142a provided in the insulating layer 116, the insulating layer 118, the insulating layer 104, and the insulating layer 103. The conductive layer 120c is electrically connected to the conductive layer 112 through an opening 142b provided in the insulating layer 116. Thus, the same potential can be supplied to the conductive layer 106 and the conductive layer 112.

The above is the description of Structure Example 2.

### Modification Example

Modification examples of Structure Example 1 and Structure Example 2 will be described below.

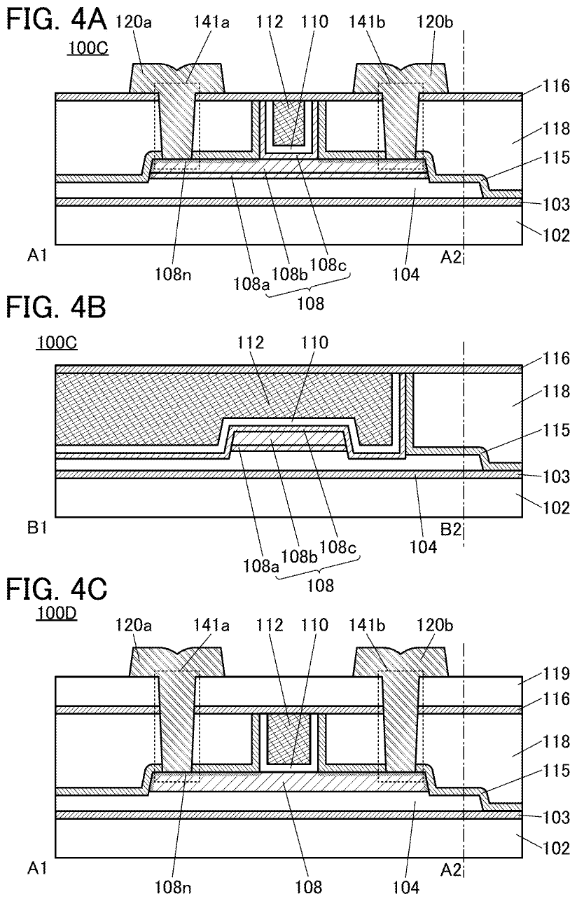

FIGS. 4(A) and 4(B) are a cross-sectional view in the channel length direction of a transistor 100C and a cross-sectional view in the channel width direction thereof. The transistor 100C differs from the above Structural Example 1 mainly in a structure of the semiconductor layer 108.

The semiconductor layer 108 includes a semiconductor layer 108c. The semiconductor layer 108c is provided in an opening in the insulating layer 118 so as to be positioned between the insulating layer 110 and the insulating layer 115 and between the insulating layer 110 and the semiconductor layer 108b.

The semiconductor layer 108c can be formed using the same material as that for one of the semiconductor layer 108a and the semiconductor layer 108b or a material different from those for the semiconductor layer 108a and the semiconductor layer 108b. For example, the semiconductor layer 108c can use a material having a difference in at least one of crystallinity, composition, and impurity concentration from one of the semiconductor layer 108a and the semiconductor layer 108b or both thereof.

When a semiconductor film to be the semiconductor layer 108c is deposited by a sputtering method, the flow rate ratio of an oxygen gas to the total flow rate of a deposition gas is set high. This enables oxygen to be supplied effectively to the semiconductor layer 108b and the semiconductor layer 108a in the channel formation region during deposition of the semiconductor film. The oxygen-gas flow rate ratio is higher than or equal to 50% and lower than or equal to 100%, preferably higher than or equal to 70% and lower than or equal to 100%, further preferably higher than or equal to 90% and lower than or equal to 100%, still further preferably 100%.

FIG. 4(C) is a cross-sectional view of a transistor 100D in the channel length direction. The transistor 100D differs from the above Structural Example 1 mainly in that the semiconductor layer 108 has a single-layer structure.

When the semiconductor layer 108 has a single-layer structure in this manner, the manufacturing process can be simplified.

FIG. 4(C) illustrates an example in which an insulating layer 119 is further provided over the insulating layer 116, and the conductive layer 120a and the conductive layer 120b are provided over the insulating layer 119. The insulating layer 119 is preferably provided, in which case parasitic capacitance between the conductive layer 112 and the conductive layer 120a or the conductive layer 120b can be reduced.

Note that in the transistor 100C and the transistor 100D, the conductive layer 106 described in Structure Example 2 can be provided.

The above is the description of the modification example.

### [Components of Semiconductor Device]

Next, components included in the semiconductor device of this embodiment will be described in detail.

### [Substrate]

Although there is no particular limitation on a material and the like of the substrate 102, it is necessary that the substrate have at least heat resistance high enough to withstand heat treatment performed later. For example, a single crystal semiconductor substrate or a polycrystalline semiconductor substrate including silicon or silicon carbide as a material, a compound semiconductor substrate of silicon germanium or the like, an SOT substrate, a glass substrate, a ceramic substrate, a quartz substrate, a sapphire substrate, or the like may be used as the substrate 102. Alternatively, any of these substrates over which a semiconductor element is provided may be used as the substrate 102.

A flexible substrate may be used as the substrate 102, and the transistor 100 or the like may be formed directly on the flexible substrate. Alternatively, a separation layer may be provided between the substrate 102 and the transistor 100 and the like. The separation layer can be used for separation of part or the whole of a semiconductor device completed thereover from the substrate 102 and transferring the part or the whole of the semiconductor device onto another substrate. In such a case, the transistor 100 or the like can be transferred onto a substrate having low heat resistance or a flexible substrate as well.

### [Insulating Layer 104]

The insulating layer 104 can be formed by a sputtering method, a CVD method, an evaporation method, a pulsed laser deposition (PLD) method, or the like as appropriate. For example, the insulating layer 104 can be formed to have a single layer or a stacked layer including an oxide insulating film or a nitride insulating film. To improve the properties of the interface with the semiconductor layer 108, at least a region in the insulating layer 104, which is in contact with the semiconductor layer 108, is preferably formed using an oxide insulating film. The insulating layer 104 is preferably formed using a film from which oxygen is released by heating.

For example, a single layer or stacked layers using silicon oxide, silicon oxynitride, silicon nitride oxide, silicon nitride, aluminum oxide, hafnium oxide, gallium oxide, a Ga—Zn oxide, or the like can be provided as the insulating layer 104.

In the case where a film other than an oxide film, e.g., a silicon nitride film, is used for the side of the insulating layer 104 that is in contact with the semiconductor layer 108, pretreatment such as oxygen plasma treatment is preferably performed on the surface in contact with the semiconductor layer 108 to oxidize the surface or the vicinity of the surface.

[Conductive Film]

The conductive layers 112 and 106 functioning as gate electrodes, the conductive layer 120a functioning as one of a source electrode and a drain electrode, and the conductive layer 120b functioning as the other electrode can each be formed using a metal element selected from chromium, copper, aluminum, gold, silver, zinc, molybdenum, tantalum, titanium, tungsten, manganese, nickel, iron, and cobalt; an alloy containing any of these metal elements as its component; an alloy including a combination of any of these metal elements; or the like.

For the conductive layer 112, the conductive layer 106, the conductive layer 120a, and the conductive layer 120b, an oxide conductor or a metal oxide film such as an In—Sn oxide, an In—W oxide, an In—W—Zn oxide, an In—Ti oxide, an In—Ti—Sn oxide, an In—Zn oxide, an In—Sn—Si oxide, or an In—Ga—Zn oxide can also be used.

Here, an oxide conductor (OC) is described. For example, when an oxygen vacancy is formed in a metal oxide having semiconductor characteristics and hydrogen is added to the oxygen vacancy, a donor level is formed in the vicinity of the conduction band. As a result, the conductivity of the metal oxide is increased, so that the metal oxide becomes a conductor. The metal oxide having become a conductor can be referred to as an oxide conductor.

The conductive layer 112 or the like may have a stacked-layer structure of a conductive film containing the above-described oxide conductor (metal oxide) and a conductive film containing a metal or an alloy. The use of the conductive film containing a metal or an alloy can reduce the wiring resistance. At this time, the conductive film in contact with the insulating layer functioning as a gate insulating film is preferably a conductive film containing an oxide conductor.

Among the above-mentioned metal elements, any one or more selected from titanium, tungsten, tantalum, and molybdenum is preferably included in the conductive layers 112, 106, 120a, and 120b. It is especially preferable to use a tantalum nitride film. The tantalum nitride film has conductivity, has a high barrier property against copper, oxygen, or hydrogen, and releases little hydrogen from itself; accordingly the tantalum nitride film is suitable as a conductive film that is in contact with the semiconductor layer 108 or a conductive film that is in the vicinity of the semiconductor layer 108.

### [Insulating Layer 110]

The insulating layer 110 functioning as a gate insulating film, such as the transistor 100, can be formed by a PECVD method, a sputtering method, or the like. As the gate insulating layer 110, an insulating layer including one or more of a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film can be used. Note that the insulating layer 110 may have a stacked-layer structure of two layers or a stacked-layer structure of three or more layers.

The insulating layer 110 that is in contact with the semiconductor layer 108 is preferably an oxide insulating film and preferably includes a region including oxygen in excess of that in the stoichiometric composition. In other words, the insulating layer 110 is an insulating film capable of releasing oxygen. For example, it is also possible to supply oxygen into the insulating layer 110 by forming the insulating layer 110 in an oxygen atmosphere, performing heat treatment, plasma treatment, or the like on the formed insulating layer 110 in an oxygen atmosphere, or forming an oxide film over the insulating layer 110 in an oxygen atmosphere.

For the insulating layer 110, a material having a larger dielectric constant than silicon oxide or silicon oxynitride, such as hafnium oxide, can also be used. In that case, the insulating layer 110 can be thick and leakage current due to tunnel current can be inhibited. Specifically, hafnium oxide having crystallinity is preferable because it has a higher dielectric constant than amorphous hafnium oxide.

### [Semiconductor Layer]

In the case where the semiconductor layer 108 is an In-M-Zn oxide, a sputtering target used to deposit the In-M-Zn oxide preferably satisfies the following atomic ratio: In >M. Examples of the atomic ratio of the metal elements in such a sputtering target includes In:M:Zn=1:1:1, In:M:Zn=1:1:1.2, In:M:Zn=2:1:3, In:M:Zn=3:1:2, In:M:Zn=4:2:4.1, In:M:Zn=5:1:6, In:M:Zn=5:1:7, In:M:Zn=5:1:8, In:M:Zn=6:1:6, In:M:Zn=5:2:5, and the like.

A target containing a polycrystalline oxide is preferably used as the sputtering target, in which case the semiconductor layer 108 having crystallinity is easily formed. Note that the atomic ratio in the semiconductor layer 108 to be formed varies in the range of ±40% from any of the above atomic ratios of the metal elements contained in the sputtering target. For example, in the case where the composition of the sputtering target used for the semiconductor layer 108 is In:Ga:Zn=4:2:4.1 [atomic ratio], the composition of the semiconductor layer 108 to be formed is in some cases in the neighborhood of In:Ga:Zn=4:2:3 [atomic ratio].

Note that when the atomic ratio is described as In:Ga:Zn=4:2:3 or as being in the neighborhood thereof, the case is included where the atomic proportion of Ga is greater than or equal to 1 and less than or equal to 3 and the atomic proportion of Zn is greater than or equal to 2 and less than or equal to 4 with the atomic proportion of In being 4. When the atomic ratio is described as In:Ga:Zn=5:1:6 or as being in the neighborhood thereof, the case is included where the atomic proportion of Ga is greater than 0.1 and less than or equal to 2 and the atomic proportion of Zn is greater than or equal to 5 and less than or equal to 7 with the atomic proportion of In being 5. When the atomic ratio is described as In:Ga:Zn=1:1:1 or as being in the neighborhood thereof, the case is included where the atomic proportion of Ga is greater than 0.1 and less than or equal to 2 and the atomic proportion of Zn is greater than 0.1 and less than or equal to 2 with the atomic proportion of In being 1.

The energy gap of the semiconductor layer 108 is 2 eV or more, preferably 2.5 eV or more. With use of a metal oxide having a wider energy gap than silicon, the off-state current of the transistor can be reduced.

Furthermore, the semiconductor layer 108 preferably has a non-single-crystal structure. Examples of the non-single-crystal structure include a CAAC structure which will be described later, a polycrystalline structure, a microcrystalline structure, and an amorphous structure. Among the non-single-crystal structures, the amorphous structure has the highest density of defect states, whereas the CAAC structure has the lowest density of defect states.

A CAAC (c-axis aligned crystal) will be described below. A CAAC is one example of crystal structures.

Note that the CAAC structure is a crystal structure of a thin film or the like that has a plurality of nanocrystals (crystal regions having a maximum diameter less than 10 nm), and characterized in that the nanocrystals have c-axis alignment in a particular direction and are not aligned but continuously connected in the a-axis and b-axis directions without forming a grain boundary. In particular, a thin film having the CAAC structure is characterized in that the c-axes of nanocrystals are likely to be aligned in the thin-film thickness direction, the normal direction of the surface where the thin film is formed, or the normal direction of the surface of the thin film.

A CAAC-OS (Oxide Semiconductor) is an oxide semiconductor with high crystallinity. On the other hand, a clear crystal grain boundary cannot be observed in the CAAC-OS; thus, it can be said that a reduction in electron mobility due to the crystal grain boundary is less likely to occur. Furthermore, entry of impurities, formation of defects, or the like might cause a decrease in the crystallinity of an oxide semiconductor, which means that the CAAC-OS is an oxide semiconductor having small amounts of impurities and defects (e.g., oxygen vacancies). Thus, an oxide semiconductor including a CAAC-OS is physically stable. Therefore, the oxide semiconductor including a CAAC-OS is resistant to heat and has high reliability.

Here, in crystallography, in a unit cell formed with three axes (crystal axes) of the a-axis, the b-axis, and the c-axis, a specific axis is generally taken as the c-axis. In particular, in the case of a crystal having a layered structure, two axes parallel to the plane direction of a layer are regarded as the a-axis and the b-axis and an axis intersecting with the layer is regarded as the c-axis in general. Typical examples of such a crystal having a layered structure include graphite, which is classified as a hexagonal system. In a unit cell of graphite, the a-axis and the b-axis are parallel to the cleavage plane and the c-axis is orthogonal to the cleavage plane. For example, an InGaZnO₄ crystal having a YbFe₂O₄ type crystal structure, which is a layered structure, can be classified as a hexagonal system, and in a unit cell thereof, the a-axis and the b-axis are parallel to the plane direction of the layer and the c-axis is orthogonal to the layer (i.e., orthogonal to the a-axis and the b-axis).

An example of a crystal structure of a metal oxide is described. Note that a metal oxide deposited by a sputtering method using an In—Ga—Zn oxide target (In:Ga:Zn=4:2:4.1 [atomic ratio]) is described below as an example. A metal oxide that is deposited by a sputtering method using the above target at a substrate temperature higher than or equal to 100° C. and lower than or equal to 130° C. is likely to have either the nc (nano crystal) structure or the CAAC structure, or a structure in which both structures are mixed. In contrast, a metal oxide deposited by a sputtering method at a substrate temperature set at room temperature (R.T.) is likely to have the nc structure. Note that room temperature (R.T.) here also includes a temperature in the case where a substrate is not heated intentionally.

### [Manufacturing Method Example]

A manufacturing method example of a transistor of one embodiment of the present invention will be described below. Here, description will be made giving, as an example, the transistor 100A described above in Structural Example 2.

Note that thin films that form the semiconductor device (insulating films, semiconductor films, conductive films, and the like) can be formed by a sputtering method, a chemical vapor deposition (CVD) method, a vacuum evaporation method, a pulse laser deposition (PLD) method, an atomic layer deposition (ALD) method, or the like. Examples of the CVD method include a plasma-enhanced CVD (PECVD) method and a thermal CVD method. In addition, as an example of the thermal CVD method, a metal organic CVD (MOCVD) method can be given.

The thin films that form the semiconductor device (insulating films, semiconductor films, conductive films, and the like) can be formed using a method such as spin coating, dipping, spray coating, ink-jetting, dispensing, screen printing, or offset printing, or a tool such as a doctor knife, slit coating, roll coating, curtain coating, or knife coating.

When the thin films that form the semiconductor device are processed, a photolithography method or the like can be used for the processing. Besides, a nanoimprinting method, a sandblasting method, a lift-off method, or the like may be used for the processing of the thin films. Island-shaped thin films may be directly formed by a film formation method using a blocking mask such as a metal mask.

There are two typical examples of a photolithography method. In one of the methods, a resist mask is formed over a thin film that is to be processed, the thin film is processed by etching or the like, and then the resist mask is removed. In the other method, after a photosensitive thin film is formed, exposure and development are performed, so that the thin film is processed into a desired shape.

For light for exposure in a photolithography method, for example, an i-line (with a wavelength of 365 nm), a g-line (with a wavelength of 436 nm), an h-line (with a wavelength of 405 nm), or combined light of any of them can be used. Besides, ultraviolet light, KrF laser light, ArF laser light, or the like can be used. Furthermore, exposure may be performed by liquid immersion light exposure technique. Furthermore, as the light used for the exposure, extreme ultra-violet (EUV) light or X-rays may be used. Furthermore, instead of the light used for the exposure, an electron beam can also be used. It is preferable to use extreme ultra-violet light, X-rays, or an electron beam because extremely minute processing can be performed. Note that in the case of performing exposure by scanning of a beam such as an electron beam, a photomask is not needed.

For etching of the thin film, a dry etching method, a wet etching method, a sandblast method, or the like can be used.

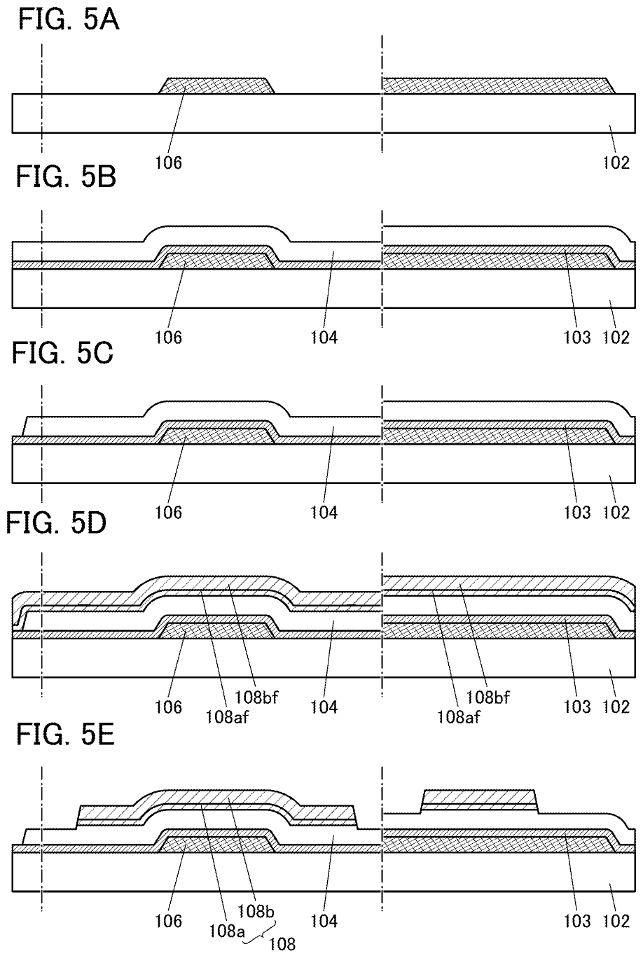

Each diagram of FIG. 5 to FIG. 8 shows cross sections in the channel length and channel width directions, side by side, of the transistor 100A in each step in the manufacturing process. In addition, a cross section of a peripheral portion of the semiconductor device is illustrated on the left side in each drawing.

### [Formation of Conductive Layer 106]

A conductive film is formed over the substrate 102 and processed by etching, whereby the conductive layer 106 functioning as a gate electrode is formed (FIG. 5(A)).

[Formation of Insulating layer 103 and Insulating layer 104]

Next, a stack of the insulating layers 103 and 104 is formed to cover the substrate 102 and the conductive layer 106 (FIG. 5(B)). Each of the insulating layers 103 and 104 can be formed by a PECVD method, an ALD method, a sputtering method, or the like.

For example, the insulating layer 103 can be formed by an ALD method or a sputtering method, and the insulating layer 104 can be formed by a PECVD method or a sputtering method.

Next, part of the insulating layer 104 that is positioned at an end portion of the semiconductor device is removed by etching (FIG. 5(C)).

### [Formation of Semiconductor Layer 108]

Next, a metal oxide film 108af and a metal oxide film 108bf are formed over the insulating layer 104 (FIG. 5(D)).

The metal oxide film 108af and the metal oxide film 108bf (hereinafter, referred to as metal oxide film collectively) are preferably formed by a sputtering method using a metal oxide target.

In forming the metal oxide film, an inert gas (e.g., a helium gas, an argon gas, or a xenon gas) may be mixed in addition to an oxygen gas. Note that the proportion of the oxygen gas in the whole deposition gas (hereinafter also referred to as an oxygen flow rate ratio) in forming the metal oxide film is higher than or equal to 0% and lower than or equal to 100%, preferably higher than or equal to 5% and lower than or equal to 20%. When the oxygen flow rate ratio is higher, the crystallinity of the metal oxide film can be higher, and a highly reliable transistor can be obtained. On the other hand, when the oxygen flow rate ratio is lower, the crystallinity of the metal oxide film is lower, and a transistor with a high on-state current can be obtained.

As film formation conditions of the metal oxide film, the substrate temperature is preferably set to higher than or equal to room temperature and lower than or equal to 200° C., preferably higher than or equal to room temperature and lower than or equal to 140° C. For example, when the film formation temperature is higher than or equal to room temperature and lower than 140° C., high productivity is achieved, which is preferable. When the metal oxide film is formed with the substrate temperature set at room temperature or without intentional heating, the crystallinity can be made low.

It is preferable to perform treatment for desorbing water, hydrogen, a component of an organic substance, or the like adsorbed onto a surface of the insulating layer 104 or treatment for supplying oxygen into the insulating layer 104 before formation of the metal oxide film. For example, heat treatment can be performed at a temperature higher than or equal to 70° C. and lower than or equal to 200° C. in a reduced-pressure atmosphere. Alternatively, plasma treatment may be performed in an oxygen-containing atmosphere. When plasma treatment containing a N₂O gas is performed, an organic substance on the surface of the insulating layer 104 can be favorably removed. After such treatment, the metal oxide film is preferably formed successively without exposure of the surface of the insulating layer 104 to the air.

Next, the metal oxide film is processed into the island-shaped semiconductor layer 108a and the semiconductor layer 108b (FIG. 5(E)).

For processing of the metal oxide film, one of a wet etching method and a dry etching method or both thereof can be used. At this time, part of the insulating layer 104 that does not overlap with the semiconductor layer 108 is etched and thinned, as shown in FIG. 5(E), in some cases.

After the metal oxide film is formed or processed into the semiconductor layer 108, heat treatment may be performed to remove hydrogen or water in the metal oxide film or the semiconductor layer 108. The temperature of the heat treatment is typically higher than or equal to 150° C. and lower than the strain point of the substrate, higher than or equal to 250° C. and lower than or equal to 450° C., or higher than or equal to 300° C. and lower than or equal to 450° C.

The heat treatment can be performed in an atmosphere containing a rare gas or nitrogen. Alternatively, heating may be performed in the atmosphere, and then heating may be performed in an oxygen-containing atmosphere. It is preferable that the atmosphere of the above heat treatment not contain hydrogen, water, or the like. An electric furnace, an RTA apparatus, or the like can be used for the heat treatment. The use of the RTA apparatus can shorten the heat treatment time.

### [Formation of Dummy Layer 113]

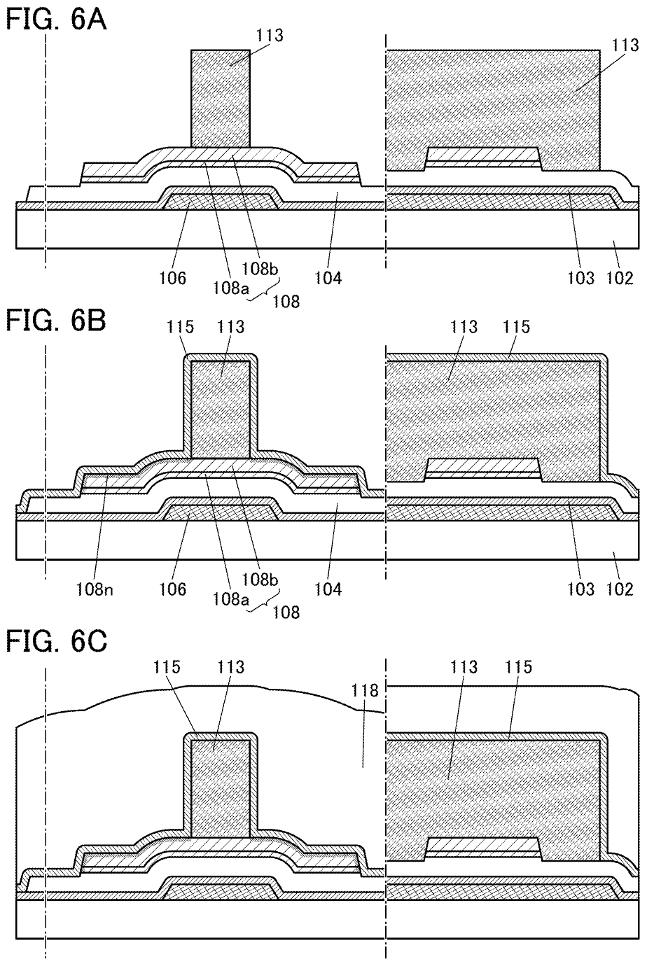

Next, a dummy layer 113 is formed over the semiconductor layer 108 and the insulating layer 104 (FIG. 6(A)). The dummy layer 113 is a layer for forming an opening in which the conductive layer 112 and the insulating layer 110 are provided in a later step.

The dummy layer 113 can be formed in the following manner: a thin film is formed and then an unnecessary portion is removed by etching. As a material of the dummy layer 113, it is preferable to select, as appropriate, a material which allows a high etching-rate selectivity with respect to the semiconductor layer 108 and the insulating layer 104. For example, in the case where a crystalline metal oxide film is used as the semiconductor layer 108b, a metal oxide film having low crystallinity (e.g., having a microcrystalline structure) can be used. Note that although not shown here, part of the insulating layer 104 might be thinned in etching of the dummy layer 113.

The dummy layer 113 is preferably formed to have a large thickness in consideration of a reduction in thickness by planarization treatment performed twice in a later step.

### [Formation of Insulating Layer 115]

Next, the insulating layer 115 is formed so as to cover the insulating layer 104, the semiconductor layer 108, and the dummy layer 113 (FIG. 6(B)). At this time, at an end portion of the semiconductor device, a region in which the insulating layer 115 is in contact with the insulating layer 103 is formed.

The insulating layer 115 is preferably formed by a reactive sputtering method using a mixed gas of a nitrogen gas and a rare gas that is a dilution gas or the like as a deposition gas with use of a sputtering target containing the above metal element. Thus, the film quality of the insulating layer 115 can be easily controlled by controlling the flow rate ratio of the deposition gas.

For example, in the case where an aluminum nitride film formed by a reactive sputtering method using an aluminum target is used as the insulating layer 115, the ratio of the nitrogen-gas flow rate to the total flow rate of the deposition gas is preferably higher than or equal to 30% and lower than or equal to 100%, further preferably higher than or equal to 40% and lower than or equal to 100%, still further preferably higher than or equal to 50% and lower than or equal to 100%.

At the time of deposition of the insulating layer 115, the low-resistance regions 108n are formed at an interface where the semiconductor layer 108 is in contact with the insulating layer 115 and a region in the vicinity thereof

### [First Heat Treatment]

Next, heat treatment is preferably performed. By the heat treatment, the reduction in the resistance of the regions 108n in the semiconductor layer 108 can be further promoted.

The heat treatment is preferably performed in an inert gas atmosphere such as nitrogen or a rare gas. The temperature of the heat treatment is preferably as high as possible and can be set in consideration of the heat resistance of the substrate 102, the conductive layer 106, the dummy layer 113, and the like. The temperature can be set, for example, higher than or equal to 120° C. and lower than or equal to 500° C., preferably higher than or equal to 150° C. and lower than or equal to 450° C., further preferably higher than or equal to 200° C. and lower than or equal to 400° C., still further preferably higher than or equal to 250° C. and lower than or equal to 400° C. When the temperature of the heat treatment is approximately 350° C., for example, the semiconductor device can be manufactured at a high yield with production facilities using a large-size glass substrate.

Note that the heat treatment may be performed at any time after the formation of the insulating layer 115. In addition, this heat treatment may also serve as another heat treatment.

By the heat treatment, for example, oxygen in the semiconductor layer 108 is extracted toward the insulating layer 115 side, whereby oxygen vacancy is generated. The oxygen vacancy and hydrogen in the semiconductor layer 108 are combined, thereby increasing the carrier concentration and lowering the resistance of portions in contact with the insulating layer 115.

Alternatively, in some cases, the heat treatment causes the diffusion of a metal element contained in the semiconductor layer 108 toward the vicinity of the interface with the insulating layer 115, whereby a region with a high concentration of the metal element is formed and the resistance is lowered. For example, in the case where a metal oxide film containing indium is used for the semiconductor layer 108, a region with a high concentration of indium is sometimes observed in the vicinity of the interface between the semiconductor layer 108 and the insulating layer 115.

The regions 108n whose resistance is reduced by such a combined action becomes low-resistance regions that are extremely stable. The regions 108n formed in the above manner have a feature such that an increase in resistance is less likely to occur again even when treatment for supplying oxygen is performed in a later step, for example.

[Formation of Insulating Layer 118]

Next, the insulating layer 118 covering the insulating layer 115 is formed (FIG. 6(C)). The insulating layer 118 is preferably formed to be thick enough considering a reduction in thickness by planarization treatment performed later. The insulating layer 118 can be formed, for example, by a PECVD method.

### [First Planarization Treatment]

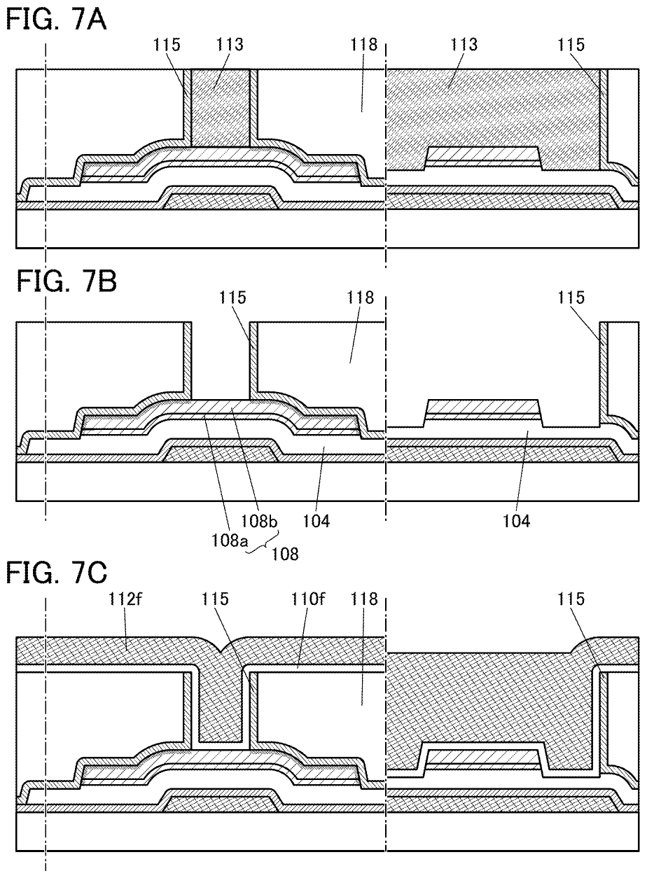

Next, planarization treatment is performed on the insulating layer 118, the insulating layer 115, and the dummy layer 113 to expose the upper portion of the dummy layer 113 (FIG. 7(A)).

For the planarization treatment, a polishing method such as a chemical mechanical polishing (CMP) method can be typically used. Alternatively, dry etching treatment or plasma treatment may be used. Note that, polishing treatment, dry etching treatment, or plasma treatment may be performed a plurality of times, or these treatments may be performed in combination. In the case where the treatments are combined, the order of steps is not particularly limited and may be set as appropriate depending on the roughness of the surface to be processed.

### [Removal of Dummy Layer 113]

Next, the dummy layer 113 is removed by etching (FIG. 7(B)). As a result, an opening of the insulating layer 118 is formed over the channel formation region of the semiconductor layer 108. In this case, a structure in which the insulating layer 115 is provided in contact with an inner wall of the opening in the insulating layer 118 can be formed.

Note that as illustrated in FIG. 7(B), part of the insulating layer 104 may be thinned in some cases, when the dummy layer 113 is etched.

[Formation of Insulating Film 110f and Conductive Film 112f]

Next, an insulating film 110f is formed to fill the opening, and a conductive film 112f is successively (FIG. 7(C)).

The insulating film 110f is preferably formed using, for example, an oxide film such as a silicon oxide film or a silicon oxynitride film with a plasma-enhanced chemical vapor deposition apparatus (a PECVD apparatus or simply referred to as a plasma CVD apparatus). Alternatively, the insulating film 110f may be formed by a PECVD method using a microwave. Alternatively, the insulating film 110f can be formed by a CVD method using an organosilane gas.

The conductive film 112f preferably contains a material that inhibits penetration of oxygen. For example, tantalum nitride, tungsten nitride, titanium nitride, or the like can be used. Alternatively, a stacked film of a conductive film containing such a material and a conductive film containing tantalum, tungsten, titanium, molybdenum, aluminum, copper, molybdenum, a tungsten alloy, or the like may be used. In that case, it is preferable that the conductive film positioned on the upper side be thicker than the conductive film positioned on the lower side and contain a material having high conductivity. The conductive film 112f can be deposited by a sputtering method, a CVD method, an MBE method, a PLD method, an ALD method, or the like, for example.

In the case where the conductive film 112f has a multilayer structure, for example, the conductive film positioned on the lower side can be deposited by a sputtering method, an ALD method, or the like, and then the conductive film positioned on the upper side can be deposited by a plating method, a sputtering method, a CVD method, an MBE method, a PLD method, an ALD method, or the like. By this, a void or the like is less likely to be formed in the embedded conductive film 112f

### [Second Planarization Treatment]

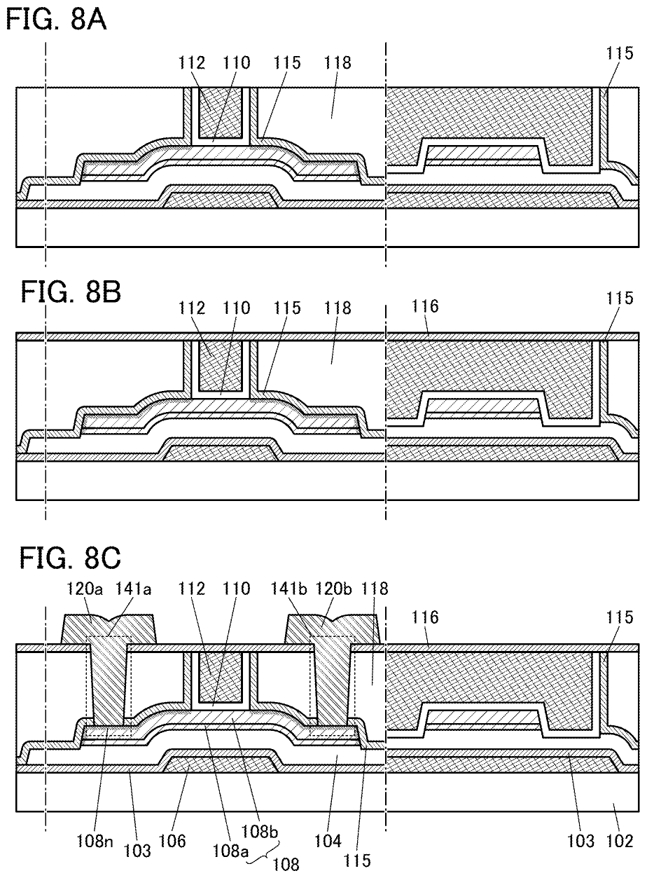

Next, second planarization treatment is performed on the conductive film 112f, the insulating film 110f, the insulating layer 115, and the insulating layer 118 to expose the upper portion of the insulating layer 118 (FIG. 8(A)). The second planarization treatment can be performed in a similar manner to that of the first planarization treatment.

By the second planarization treatment, the conductive layer 112 and the insulating layer 110 can be formed.

### [Formation of Insulating Layer 116]

Next, the insulating layer 116 is formed over the insulating layer 118, the insulating layer 115, the insulating layer 110, and the conductive layer 112 (FIG. 8(B)). The insulating layer 116 can be formed in a manner similar to that of the insulating layer 103.

### [Second Heat Treatment]

Next, second heat treatment is preferably performed. The second heat treatment can be performed under a condition similar to that of the above first heat treatment.

Through the second heat treatment, oxygen released from the insulating layer 104 can be supplied to the semiconductor layer 108; thus, oxygen vacancy in the semiconductor layer 108 can be reduced. The oxygen released from the insulating layer 110 can also be supplied to the channel formation region of the semiconductor layer 108.

In this structure, since the insulating layer 115 inhibits the semiconductor layer 108, the insulating layer 110, and the insulating layer 104 from being in contact with the insulating layer 118, hydrogen contained in the insulating layer 118 can be prevented from diffusing into the semiconductor layer 108 and the like, and oxygen contained in the semiconductor layer 108 and the like is prevented from diffusing to the insulating layer 118 side. Since the insulating layers 103 and 116 are provided, it is possible to effectively prevent the diffusion of hydrogen from the outside or the substrate 102 side to the insulating layer 104 or 110 or the diffusion of oxygen from the insulating layer 104 or 110 to the outside.

[Formation of Openings 141a and 141b]

Next, a mask is formed by lithography in a desired position on the insulating layer 116, and then the insulating layer 116, the insulating layer 118, and the insulating layer 115 are partly etched, so that an opening 141a and an opening 141b reaching the regions 108n are formed.

Note that in the case where the transistor 100B illustrated in FIG. 3 is formed, the opening 142a reaching the conductive layer 106 and the opening 142b reaching the conductive layer 112 may be formed in this step.

[Formation of Conductive Layers 120a and 120b]

Next, a conductive film is formed over the insulating layer 116 so as to cover the opening 141a and the opening 141b, and the conductive film is processed into a desired shape, whereby the conductive layer 120a and the conductive layer 120b are formed (FIG. 8(C)).

In the case where the transistor 100B illustrated in FIG. 3 is formed, the conductive layer 120c may be concurrently formed in this step.

Through the above process, the transistor 100A can be manufactured.

At least part of the structural examples, the manufacturing method examples, the drawings corresponding thereto, and the like exemplified in this embodiment can be implemented in combination with the other structural examples, the other manufacturing method examples, the other drawings corresponding thereto, and the like as appropriate.

At least part of this embodiment can be implemented in combination with any of the other embodiments described in this specification as appropriate.

### Embodiment 2

In this embodiment, an example of a display device that includes the transistor exemplified in the above embodiment will be described.

### [Structure Example]

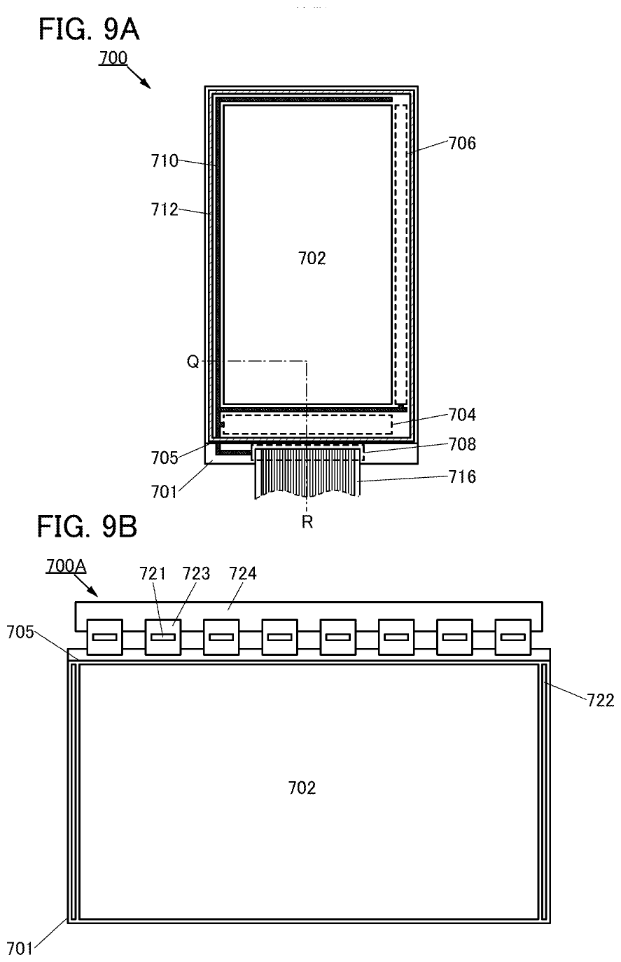

FIG. 9(A) shows a top view of a display device 700. The display device 700 includes a first substrate 701 and a second substrate 705 that are bonded to each other with a sealant 712. In the region sealed by the first substrate 701, the second substrate 705, and the sealant 712, a pixel portion 702, a source driver portion 704, and a gate driver circuit portion 706 are provided over the first substrate 701. In addition, in the pixel portion 702, a plurality of display elements are provided.

An FPC terminal portion 708 to which an FPC 716 (FPC: flexible printed circuit) is connected is provided in a portion where the first substrate 701 and the second substrate 705 do not overlap with each other. The FPC 716 supplies a variety of signals to the pixel portion 702, the source driver circuit portion 704, and the gate driver circuit portion 706 through the FPC terminal portion 708 and a signal line 710.

A plurality of the gate driver circuit portions 706 may be provided. Each of the gate driver circuit portion 706 and the source driver circuit portion 704 may be formed separately over a semiconductor substrate or the like and may be in the form of a packaged IC chip. The IC chip can be mounted over the first substrate 701 or on the FPC 716.

The transistor that is a semiconductor device of one embodiment of the present invention can be used as transistors included in the pixel portion 702, the source driver circuit portion 704, and the gate driver circuit portion 706.

Examples of the display element provided in the pixel portion 702 include a liquid crystal element and a light-emitting element. As the liquid crystal element, a transmissive liquid crystal element, a reflective liquid crystal element, a transflective liquid crystal element, or the like can be used. As an example of the light-emitting element, a self-luminous light-emitting element such as an LED (Light Emitting Diode), an OLED (Organic LED), a QLED (Quantum-dot LED), or a semiconductor laser can be given. Moreover, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can also be used, for instance.

A display device 700A illustrated in FIG. 9(B) is a display device suitably used for an electronic device with a large screen. For example, the display device 700A can be suitably used for a television device, a monitor device, digital signage, or the like.

The display device 700A includes a plurality of source driver ICs 721 and a pair of gate driver circuits 722.

The transistor that is the semiconductor device of one embodiment of the present invention can be used as transistors included in the pixel portion 702, the source driver IC 721, and the gate driver circuit 722.

The plurality of source driver ICs 721 are attached to respective FPCs 723. In each of the plurality of FPCs 723, one of terminals is connected to the first substrate 701, and the other terminal is connected to a printed circuit board 724. By bending the FPCs 723, the printed circuit board 724 can be placed on the back side of the pixel portion 702 so as to be implemented on an electronic device, whereby the space of the electronic device can be saved.

On the other hand, the gate driver circuit 722 is provided over the first substrate 701. Thus, an electronic device with a narrow frame can be obtained.

With such a structure, a large-size and high-resolution display device can be obtained. For example, such a structure can be adopted to a display device with a diagonal screen size of 30 inches or more, 40 inches or more, 50 inches or more, or 60 inches or more. Furthermore, a display device with extremely high resolution such as full high definition, 4K2K, or 8K4K can be provided.

At least part of this embodiment can be implemented in combination with any of the other embodiments described in this specification as appropriate.

### Embodiment 3

In this embodiment, a display device including the semiconductor device of one embodiment of the present invention will be described.

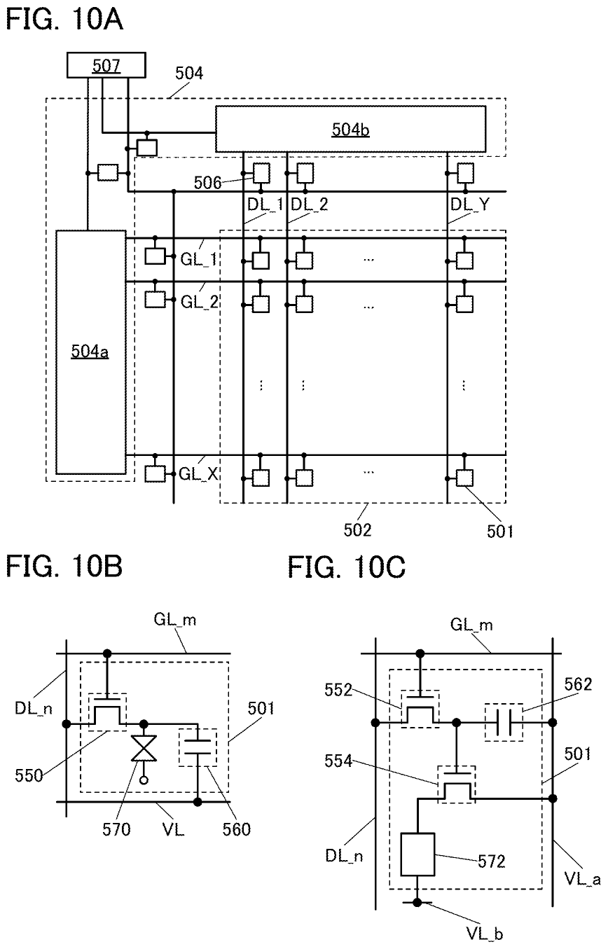

The display device in FIG. 10(A) includes a pixel portion 502, a driver circuit portion 504, a protection circuit 506, and a terminal portion 507. Note that a structure in which the protection circuit 506 is not provided may be employed.

Part or the whole of the driver circuit portion 504 is desirably formed over the same substrate as the pixel portion 502. Thus, the number of components and the number of terminals can be reduced. In the case where part or the whole of the driver circuit portion 504 is not formed over the same substrate as the pixel portion 502, the part or the whole of the driver circuit portion 504 can be incorporated by COG or TAB (Tape Automated Bonding).

The transistor of one embodiment of the present invention can be used as transistors included in the driver circuit portion 504. Furthermore, the pixel circuit portion 502 and the protection circuit 506 may also use the transistor of one embodiment of the present invention.

The pixel portion 502 includes pixel circuits 501 for driving a plurality of display elements arranged in X columns (X is a natural number of 2 or more) and Y columns (Y is a natural number of 2 or more). The driver circuit portion 504 includes driver circuits such as a gate driver 504a outputting scan signals to gate lines GL_1 to GL_X and a source driver 504b supplying data signals to data lines DL_1 to DL_Y.

The gate driver 504a may have a structure including at least a shift register.

The source driver 504b is formed using a plurality of analog switches, for example. In addition, the source driver 504b may be formed using a shift register or the like.

Note that the terminal portion 507 refers to a portion provided with terminals for inputting power, control signals, and image signals to the display device from external circuits.

The protection circuit 506 is a circuit that makes, when a potential out of a certain range is applied to the wiring connected to the protection circuit, the wiring and another wiring be in conduction state. The protection circuit 506 illustrated in FIG. 10(A) is connected to various kinds of wirings such as scanning lines GL, which are wirings between the gate driver 504a and the pixel circuits 501, and the data lines DL, which are wirings between the source driver 504b and the pixel circuits 501.

The gate driver 504a and the source driver 504b may each be provided over a substrate over which the pixel portion 502 is provided, or a substrate provided with a gate driver circuit or a source driver circuit (e.g., a driver circuit board formed using a single crystal semiconductor film or a polycrystalline semiconductor film) may be separately prepared and mounted.

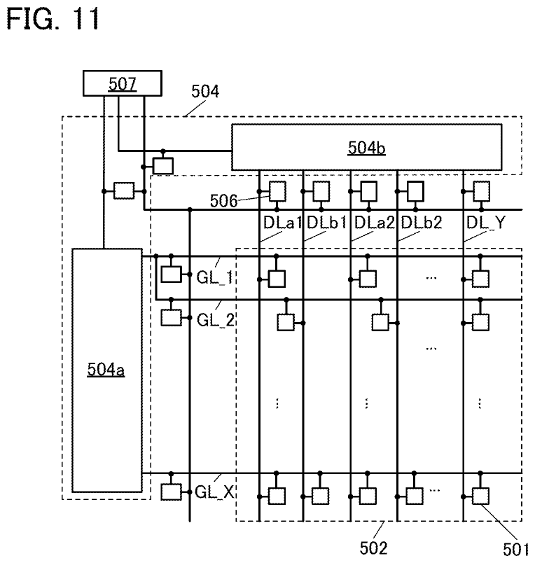

Here, FIG. 11 illustrates a structure different from that in FIG. 10(A). In FIG. 11, a pair of source lines (e.g., a source line DLa1 and a source line DLb1) is provided so that a plurality of pixels arranged in the source line direction are sandwiched therebetween. In addition, two adjacent gate lines (e.g., a gate line GL_1 and a gate line GL_2) are electrically connected to each other.

Furthermore, pixels connected to the gate line GL_1 are connected to one of the source lines (such as the source line DLa1 or a source line DLa2), and pixels connected to the gate line GL_2 are connected to the other source line (such as the source line DLb1 or a source line DLb2).

In such a configuration, two gate lines can be selected concurrently. Accordingly, one horizontal period can have a length twice that in the configuration illustrated in FIG. 10(A). Thus, this facilitates an increase in resolution and an increase in screen size of a display device.

Furthermore, the plurality of pixel circuits 501 illustrated in FIG. 10(A) and FIG. 11 can have the configuration illustrated in FIG. 10(B) or FIG. 10(C), for example.

The pixel circuit 501 illustrated in FIG. 10(B) includes a liquid crystal element 570, a transistor 550, and a capacitor 560. The data line DL_n, the scanning line GL_m, a potential supply line VL, and the like are connected to the pixel circuit 501. As the transistor 550, the transistors described in the above embodiments may be used.

The potential of one of a pair of electrodes of the liquid crystal element 570 is set in accordance with the specifications of the pixel circuit 501 as appropriate. The alignment state of the liquid crystal element 570 is set depending on written data. Note that a common potential may be supplied to one of the pair of electrodes of the liquid crystal element 570 included in each of the plurality of pixel circuits 501. Moreover, a different potential may be supplied to one of the pair of electrodes of the liquid crystal element 570 of the pixel circuit 501 in each row.

The pixel circuit 501 illustrated in FIG. 10(C) includes transistors 552 and 554, a capacitor 562, and a light-emitting element 572. The data line DL_n, the scanning line GL_m, a potential supply line VL_a, and the like are connected to the pixel circuit 501. The transistors described in the above embodiments may be used as one or both of the transistor 552 and the transistor 554.

As the light-emitting element 572, an organic electroluminescent element (also referred to as an organic EL element) or the like can be used, for example. Note that the light-emitting element 572 is not limited thereto; an inorganic EL element including an inorganic material may be used.

Note that a high power supply potential VDD is supplied to one of the potential supply line VL_a and the potential supply line VL_b, and a low power supply potential VSS is supplied to the other.

At least part of this embodiment can be implemented in combination with any of the other embodiments described in this specification as appropriate.

### Embodiment 4

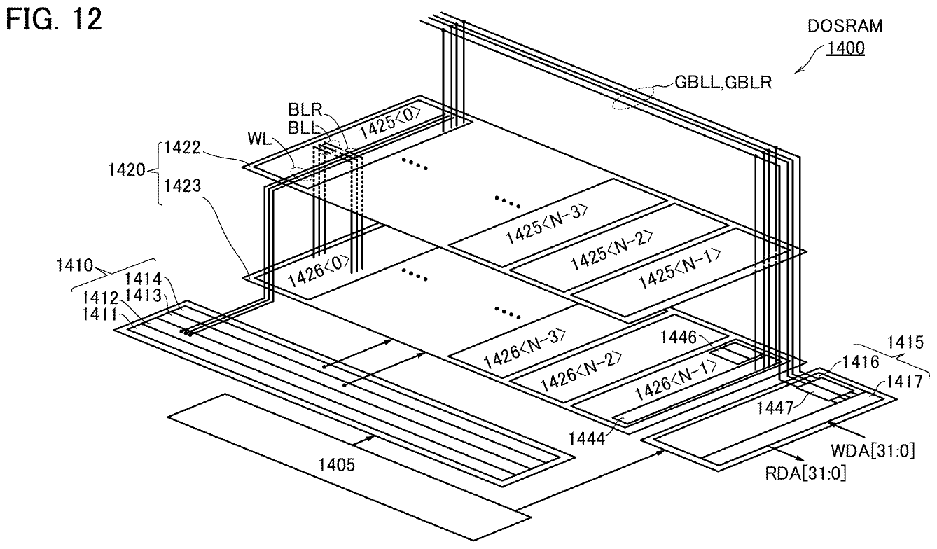

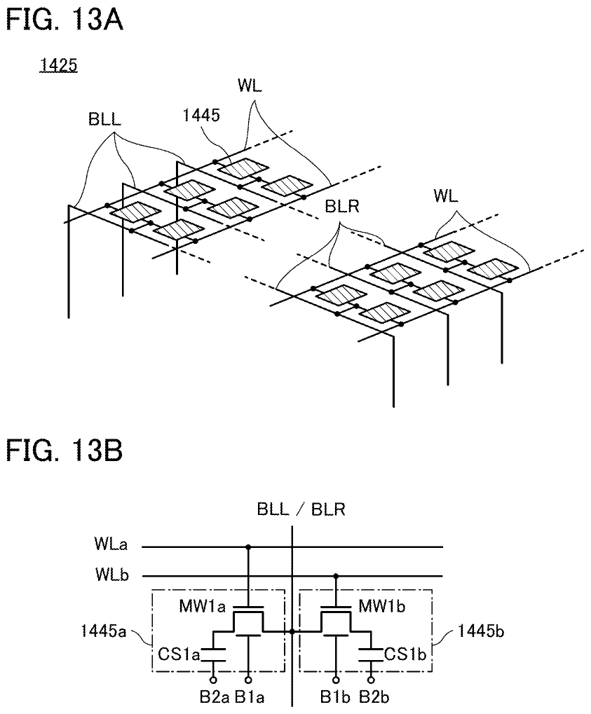

In this embodiment, a DOSRAM will be described as an example of a memory device that uses a transistor related to one embodiment of the present invention and a capacitor, with reference to FIG. 12 and FIG. 13. A DOSRAM (registered trademark) is ab abbreviation of “Dynamic Oxide Semiconductor RAM”, which indicates a RAM including 1T (transistor) 1C (capacitor)-type memory cells.

### <<DOSRAM 1400>>

FIG. 12 illustrates a structure example of the DOSRAM. As illustrated in FIG. 12, a DOSRAM 1400 includes a controller 1405, a row circuit 1410, a column circuit 1415, and a memory cell and sense amplifier array 1420 (hereinafter referred to as an “MC-SA array 1420”).

The row circuit 1410 includes a decoder 1411, a word line driver circuit 1412, a column selector 1413, and a sense amplifier driver circuit 1414. The column circuit 1415 includes a global sense amplifier array 1416 and an input/output circuit 1417. The global sense amplifier array 1416 includes a plurality of global sense amplifiers 1447. The MC-SA array 1420 includes a memory cell array 1422, a sense amplifier array 1423, and global bit lines GBLL and GBLR.

### (MC-SA Array 1420)

The MC-SA array 1420 has a stacked-layer structure where the memory cell array 1422 is stacked over the sense amplifier array 1423. The global bit lines GBLL and GBLR are stacked over the memory cell array 1422. The DOSRAM 1400 adopts, as the bit-line structure, a hierarchical bit line structure hierarchized with local bit lines and global bit lines.

The memory cell array 1422 includes N local memory cell arrays 1425<0> to 1425<N−1> (N is an integer greater than or equal to 2). FIG. 13(A) illustrates a configuration example of the local memory cell array 1425. The local memory cell array 1425 includes a plurality of memory cells 1445, a plurality of word lines WL, and a plurality of bit lines BLL and BLR. In the example in FIG. 13(A), the local memory cell array 1425 has an open bit-line architecture but may have a folded bit-line architecture.

FIG. 13(B) illustrates a circuit configuration example of a pair of a memory cell 1445a and a memory cell 1445b connected to the same bit line BLL (BLR). The memory cell 1445a includes a transistor MW1a, a capacitor CS1a, and terminals Bla and B2a, and is connected to a word line WLa and the bit line BLL (BLR). The memory cell 1445b includes a transistor MW1b, a capacitor CS1b, and terminals B1b and B2b, and is connected to a word line WLb and the bit line BLL (BLR). Hereinafter, in the case where the description is not limited to the memory cell 1445a or the memory cell 1445b, the memory cell 1445 and its components are described without using the letter “a” or “b”, in some cases.

The transistor MW1a has a function of controlling the charging and discharging of the capacitor CS1a, and the transistor MW1b has a function of controlling the charging and discharging of the capacitor CS1b. A gate of the transistor MW is electrically connected to the word line WLa, a first terminal of the transistor MW is electrically connected to the bit line BLL (BLR), and a second terminal of the transistor MW is electrically connected to a first terminal of the capacitor CS1a. A gate of the transistor MW1b is electrically connected to the word line WLb, a first terminal of the transistor MW1b is electrically connected to the bit line BLL (BLR), and a second terminal of the transistor MW1b is electrically connected to a first terminal of the capacitor CS1lb. In this way, the bit line BLL (BLR) is shared by the first terminal of the transistor MW and the first terminal of the transistor MW1b.

The transistor MW1 has a function of controlling the charging and discharging of the capacitor CS1. A second terminal of the capacitor CS1 is electrically connected to a terminal B2. A constant voltage (e.g., low power supply voltage) is input to the terminal B2.

The semiconductor device described in the above embodiment can be used for the transistor MW of the memory cell 1445a or 1445b.

The transistor MW1 includes a back gate, and the back gate is electrically connected to a terminal B1. This makes it possible to change the threshold voltage of the transistor MW1 with a voltage of the terminal B1. For example, the voltage of the terminal B1 may be a fixed voltage (e.g., a negative constant voltage); alternatively, the voltage of the terminal B1 may be changed in response to the operation of the DOSRAM 1400.

The back gate of the transistor MW1 may be electrically connected to the gate, the source, or the drain of the transistor MW1. Alternatively, the back gate is not necessarily provided in the transistor MW1.

The sense amplifier array 1423 includes N local sense amplifier arrays 1426<0> to 1426<N−1>. The local sense amplifier array 1426 includes one switch array 1444 and a plurality of sense amplifiers 1446. The sense amplifier 1446 is electrically connected to a bit line pair. The sense amplifier 1446 has a function of precharging the bit line pair, a function of amplifying a voltage difference of the bit line pair, and a function of retaining the voltage difference. The switch array 1444 has a function of selecting a bit line pair and electrically connecting the selected bit line pair and a global bit line pair to each other.

### (Controller 1405)

The controller 1405 has a function of controlling the overall operation of the DOSRAM 1400. The controller 1405 has a function of performing logic operation on a command signal that is input from the outside and determining an operation mode, a function of generating control signals for the row circuit 1410 and the column circuit 1415 so that the determined operation mode is executed, a function of retaining an address signal that is input from the outside, and a function of generating an internal address signal.

(Row Circuit 1410)

The row circuit 1410 has a function of driving the MC-SA array 1420. The decoder 1411 has a function of decoding an address signal. The word line driver circuit 1412 generates a selection signal for selecting the word line WL of a row that is to be accessed.

The column selector 1413 and the sense amplifier driver circuit 1414 are circuits for driving the sense amplifier array 1423. The column selector 1413 has a function of generating a selection signal for selecting the bit line of a column that is to be accessed. With the selection signal from the column selector 1413, the switch array 1444 of each local sense amplifier array 1426 is controlled. With the control signal from the sense amplifier driver circuit 1414, each of the plurality of local sense amplifier arrays 1426 is driven independently.

### (Column Circuit 1415)

The column circuit 1415 has a function of controlling the input of data signals WDA[31:0], and a function of controlling the output of data signals RDA[31:0]. The data signals WDA[31:0] are write data signals, and the data signals RDA[31:0] are read data signals.

The global sense amplifier 1447 is electrically connected to the global bit line pair (GBLL, GBLR). The global sense amplifier 1447 has a function of amplifying a voltage difference of the global bit line pair (GBLL, GBLR), and a function of retaining the voltage difference. Data is written to and read from the global bit line pair (GBLL, GBLR) by the input/output circuit 1417.

The DOSRAM 1400 has no limitation on the number of rewrites in principle and data can be read and written with low energy consumption, because data is rewritten by charging and discharging the capacitor CS1. In addition, the memory cell 1445 has a simple circuit configuration, and thus the capacity can be easily increased.

The transistor MW1 is a transistor including an oxide semiconductor and has extremely low off-state current; thus, leakage of charge from the capacitor CS1 can be suppressed.

Therefore, the retention time of the DOSRAM 1400 is considerably longer than that of a DRAM. This allows less frequent refresh, which can reduce power needed for refresh operations. Thus, the DOSRAM 1400 is suitably used for a memory device that can rewrite a large volume of data with a high frequency, for example, a frame memory used for image processing.

Since the MC-SA array 1420 has a stacked-layer structure, the bit line can be shortened to a length that is close to the length of the local sense amplifier array 1426. A shorter bit line results in smaller bit line capacitance, which allows the storage capacitance of the memory cell 1445 to be reduced. In addition, providing the switch array 1444 in the local sense amplifier array 1426 allows the number of long bit lines to be reduced. For the reasons described above, a load for driving while the DOSRAM 1400 is accessed is reduced, enabling a reduction in power consumption.

At least part of this embodiment can be implemented in combination with any of the other embodiments described in this specification as appropriate.

### Embodiment 5

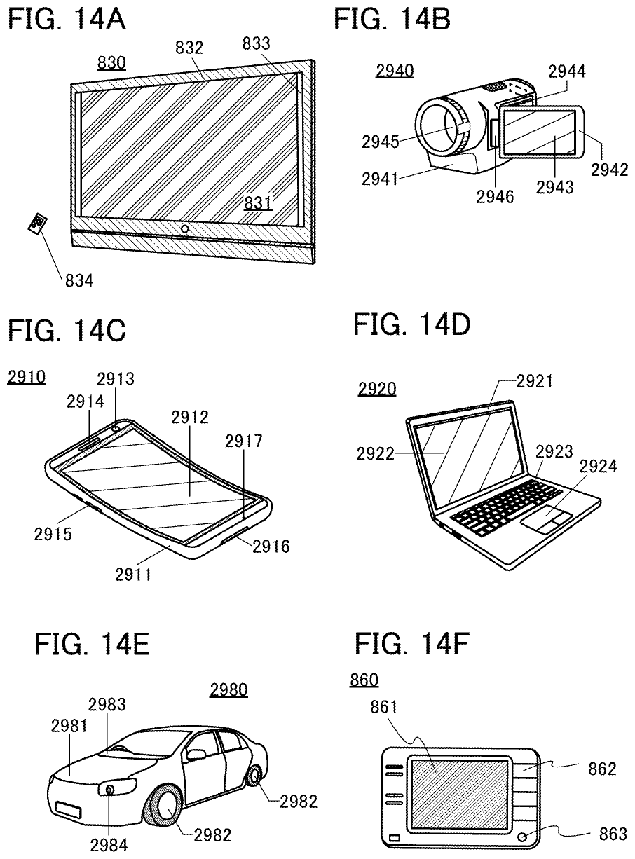

A semiconductor device of one embodiment of the present invention can be used for a variety of electronic devices. FIG. 14 illustrates specific examples of electronic devices using the semiconductor device of one embodiment of the present invention.

FIG. 14(A) illustrates a monitor 830. The monitor 830 includes a display portion 831, a housing 832, a speaker 833, and the like. Furthermore, an LED lamp, operation keys (including a power switch or an operation switch), a connection terminal, a variety of sensors, a microphone, and the like are included. The monitor 830 can be controlled with a remote controller 834.

The monitor 830 can function as a television device by receiving airwaves.

Examples of the airwaves the monitor 830 can receive include ground waves and waves transmitted from a satellite, which are for analog broadcasting, digital broadcasting, or the like. When a plurality of pieces of data received in a plurality of frequency bands are used, for example, the transfer rate can be high and a video with a resolution exceeding the full high definition can be displayed on the display portion 831. A video with a resolution of, for example, 4K2K, 8K4K, 16K8K, or more can be displayed.

A structure may be employed in which an image to be displayed on the display portion 831 is generated using broadcasting data transmitted with a technology for transmitting data via a computer network such as the Internet, a LAN (Local Area Network), or Wi-Fi (registered trademark). In this case, the monitor 830 does not need to include a tuner. The monitor 830 can be used as a computer monitor when connected to a computer. The monitor 830 can also be used as a digital signage.

The semiconductor device of one embodiment of the present invention can be used for, for example, a driver circuit or an image processing portion of the display portion. When the semiconductor device of one embodiment of the present invention is used for the driver circuit or the image processing portion of the display portion, high-speed operation or signal processing can be achieved with low power consumption.

When a processor using the semiconductor device of one embodiment of the present invention is used for the image processing portion of the monitor 830, image processing such as noise removal processing, grayscale conversion processing, color tone correction processing, or luminance correction processing can be performed. Furthermore, pixel interpolation processing due to resolution up-conversion, frame interpolation processing due to frame frequency up-conversion, or the like can be performed. In the grayscale conversion processing, not only the number of grayscale levels of an image can be changed, but also interpolation of the gray value in the case of increasing the number of grayscale levels can be performed. In addition, high-dynamic range (HDR) processing for increasing a dynamic range is also included in the grayscale conversion processing.

A video camera 2940 illustrated in FIG. 14(B) includes a housing 2941, a housing 2942, a display portion 2943, operation switches 2944, a lens 2945, a joint 2946, and the like. The operation switches 2944 and the lens 2945 are provided on the housing 2941, and the display portion 2943 is provided on the housing 2942. The video camera 2940 also includes an antenna, a battery, and the like inside the housing 2941. A structure is employed in which the housing 2941 and the housing 2942 are connected to each other with the joint 2946, and the angle between the housing 2941 and the housing 2942 can be changed with the joint 2946. The orientation of an image displayed on the display portion 2943 may be changed and display and non-display of an image can be switched depending on the angle of the housing 2942 with respect to the housing 2941.

The semiconductor device of one embodiment of the present invention can be used for, for example, a driver circuit or an image processing portion of the display portion. When the semiconductor device of one embodiment of the present invention is used for the driver circuit or the image processing portion of the display portion, high-speed operation or signal processing can be achieved with low power consumption.

When a processor using the semiconductor device of one embodiment of the present invention is used for the image processing portion of the video camera 2940, imaging appropriate for the surroundings of the video camera 2940 can be achieved. Specifically, imaging can be performed with optimal exposure for the surrounding brightness. In the case of performing imaging with backlighting or imaging under different brightness conditions such as indoors and outdoors at the same time, high-dynamic-range (HDR) imaging can be performed.

An information terminal 2910 illustrated in FIG. 14(C) includes a housing 2911 provided with a display portion 2912, a microphone 2917, a speaker portion 2914, a camera 2913, an external connection portion 2916, operation switches 2915, and the like. A display panel and a touch screen that use a flexible substrate are provided in the display portion 2912. The information terminal 2910 also includes an antenna, a battery, and the like inside the housing 2911. The information terminal 2910 can be used as, for example, a smartphone, a mobile phone, a tablet information terminal, a tablet personal computer, an e-book reader, or the like.

For example, a memory device using the semiconductor device of one embodiment of the present invention can retain control data, a control program, or the like of the information terminal 2910 for a long time.

A processor using the semiconductor device of one embodiment of the present invention can be used in the image processing portion of the information terminal 2910.

A laptop personal computer 2920 illustrated in FIG. 14(D) includes a housing 2921, a display portion 2922, a keyboard 2923, a pointing device 2924, and the like. The laptop personal computer 2920 also includes an antenna, a battery, and the like inside the housing 2921.

For example, a memory device using the semiconductor device of one embodiment of the present invention can retain control data, a control program, or the like of the laptop personal computer 2920 for a long time.

A processor using the semiconductor device of one embodiment of the present invention can be used in the image processing portion of the laptop personal computer 2920.

FIG. 14(E) is an external view illustrating an example of an automobile, and FIG. 14(F) illustrates a navigation device 860. An automobile 2980 includes a car body 2981, wheels 2982, a dashboard 2983, lights 2984, and the like. The automobile 2980 also includes an antenna, a battery, and the like. The navigation device 860 includes a display portion 861, operation buttons 862, and an external input terminal 863. The automobile 2980 and the navigation device 860 can be independent of each other; however, it is preferable that a structure be employed in which the navigation device 860 is incorporated into and linked to the automobile 2980.

For example, a memory device using the semiconductor device of one embodiment of the present invention can retain control data, a control program, or the like of the automobile 2980 or the navigation device 860 for a long time.

At least part of this embodiment can be implemented in combination with any of the other embodiments described in this specification as appropriate.

### Example

In this example, evaluation results of physical properties of an aluminum nitride film are described. In this example, evaluation results of the influence of an aluminum nitride film formed over an oxide semiconductor film on the oxide semiconductor film are also described.

Specifically, hydrogen blocking properties, oxygen blocking properties, and oxygen extraction properties in the aluminum nitride film were evaluated. Furthermore, evaluations of the sheet resistance, the hydrogen concentration, the nitrogen concentration, and the oxygen concentration in an oxide semiconductor film were conducted on baked samples in each of which an aluminum nitride film was formed over the oxide semiconductor film.

### [Evaluation 1]

In Evaluation 1, hydrogen blocking properties of the aluminum nitride film were evaluated using thermal desorption spectroscopy (TDS).

First, a sample for Evaluation 1 is described. In Evaluation 1, four types of samples were fabricated.

Each sample was fabricated in the following manner; a silicon nitride (SiN:H) film containing hydrogen was formed to have a thickness approximately 300 nm over a glass substrate; and an aluminum nitride (AlNₓ) film was formed over the silicon nitride film. The thicknesses of the aluminum film differ depending on the samples, to be 1 nm, 3 nm, 5 nm, and 20 nm.

The silicon nitride film was formed by a plasma CVD method under conditions where the flow rates of an SiH₄ gas, an N₂ gas, and an NH₃ gas were 200 sccm, 2000 sccm, and 2000 sccm, respectively, the power supply was 1000 W, the pressure was 100 Pa, and the substrate temperature was 220° C.

The aluminum nitride film was formed by a sputtering method under conditions where the ratio of the N₂ flow rate to the total amount of Ar and N₂ flow rates was 40%, the power supply was 5 kW, the pressure was 0.6 Pa, and the substrate temperature was 70° C.

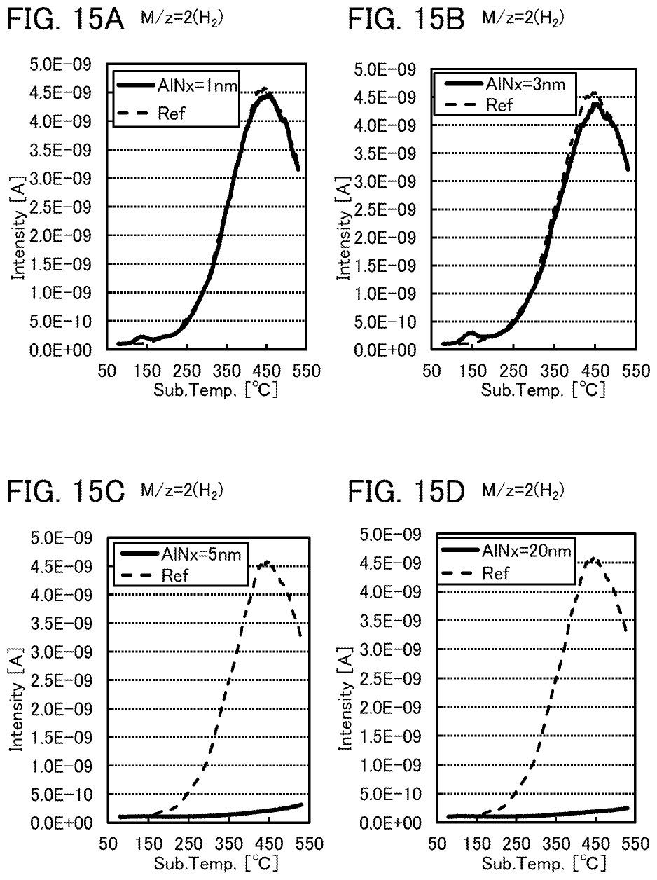

Then, each sample was subjected to TDS analysis. FIG. 15 shows TDS analysis results of the samples. In FIG. 15, the vertical axis represents the detection intensity (Intensity) of a mass-to-charge ratio of 2 (M/z=2) corresponding to hydrogen molecules (H₂), and the horizontal axis represents the substrate temperature (Sub. Temp.). Note that in FIG. 15, the dashed line indicates TDS analysis results of a comparative sample (Ref) where the aluminum nitride film (AlNx) was not formed over the silicon nitride film, for comparison.

As shown in FIGS. 15(A) and 15(B), the amount of hydrogen released from the sample where the aluminum nitride film was formed to have a thickness of 1 nm or 3 nm was substantially equal to that from the comparative sample. On the other hand, as shown in FIGS. 15(C) and 15(D), the amount of hydrogen released from the sample where the aluminum nitride film was formed to have a thickness of 5 nm or 20 nm was much smaller than that from the comparative sample.

From the above, it was found that the aluminum nitride film formed to have a thickness of 5 nm or more has high hydrogen blocking properties. The following was suggested: the aluminum nitride film formed to have a thickness of 5 nm or more serves as a cap film (barrier film) suppressing the release of hydrogen from the silicon nitride film containing hydrogen.

### [Evaluation 2]

In Evaluation 2, oxygen blocking properties of the aluminum nitride film were evaluated using TDS.

A sample for Evaluation 2 is described. In Evaluation 2, four types of samples were fabricated.

First, a silicon oxynitride (SiON) film was formed to have a thickness approximately 150 nm over a glass substrate, and an indium tin oxide containing silicon (ITSO) film was formed to have a thickness approximately 5 nm over the silicon oxynitride film. Next, oxygen radical doping treatment was conducted to supply oxygen to the silicon oxynitride film through the indium tin oxide film with an ashing apparatus. Next, the indium tin oxide film was removed. Then, an aluminum nitride (AlNₓ) film was formed over the silicon oxynitride film. The thicknesses of the aluminum nitride film differ depending on the samples to be 1 nm, 3 nm, 5 nm, and 20 nm.

The silicon oxynitride film was formed by a plasma CVD method under conditions where the flow rates of an SiH₄ gas and an N₂O gas were 20 sccm and 18000 sccm, respectively, the power supply was 100 W, the pressure was 200 Pa, and the substrate temperature was 350° C.

Conditions of the oxygen radical doping treatment were set as follows: an ICP power of 0 W, a bias power of 4500 W, a pressure of 15 Pa, an oxygen flow rate proportion of 100%, a lower electrode temperature of 40° C., and a treatment time of 120 seconds.

The aluminum nitride film was formed by a sputtering method under conditions where the ratio of the N₂ flow rate to the total amount of Ar and N₂ flow rates was 40%, the power supply was 5 kW, the pressure was 0.6 Pa, and the substrate temperature was 70° C.

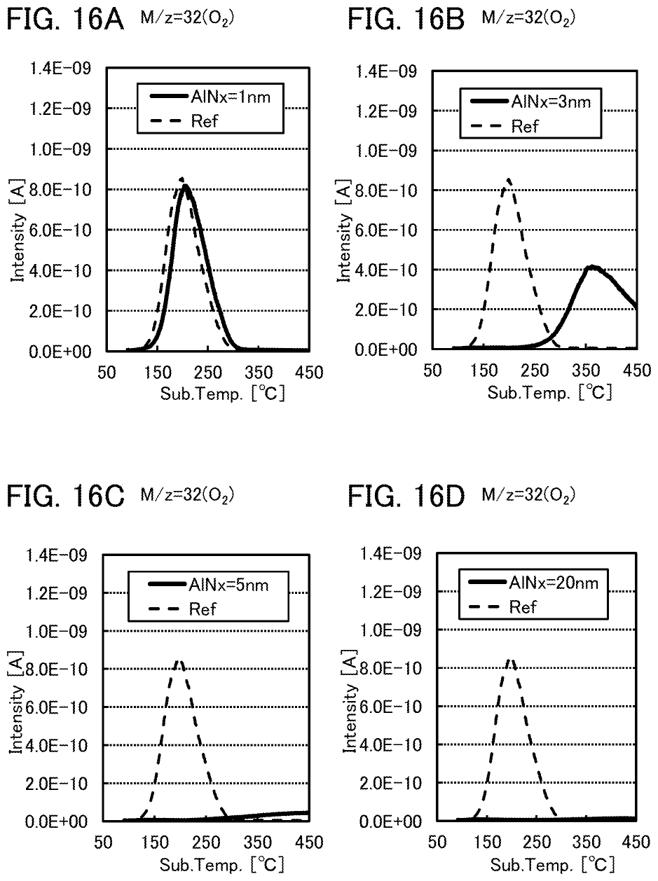

Then, each sample was subjected to TDS analysis. FIG. 16 shows TDS analysis results of the samples. In FIG. 16, the vertical axis represents the detection intensity of a mass-to-charge ratio of 32 (M/z=32) corresponding to oxygen molecules (O₂), and the horizontal axis represents the substrate temperature. Note that in FIG. 16, the dashed line indicates TDS analysis results of a comparative sample (Ref) where the aluminum nitride film was not formed over the silicon oxynitride film, for comparison.

As shown in FIG. 16(A), the amount of oxygen released from the sample where the aluminum nitride film was formed to have a thickness of 1 nm was substantially equal to that from the comparative sample. As shown in FIG. 16(B), the amount of oxygen released from the sample where the aluminum nitride film was formed to have a thickness of 3 nm was smaller than that from the comparative sample. As shown in FIGS. 16(C) and 16(D), the amount of oxygen released from the sample where the aluminum nitride film was formed to have a thickness of 5 nm or 20 nm was much smaller than that from the comparative sample.

From the above, it was found that an aluminum nitride film formed to have a thickness of 5 nm or more has high oxygen blocking properties. The following was suggested; the aluminum nitride film formed to have a thickness of 5 nm or more serves as a cap film (barrier film) suppressing the release of oxygen supplied to the silicon oxynitride film.

### [Evaluation 3]

In Evaluation 3, oxygen extraction properties of the aluminum nitride film were evaluated using TDS.

The sample for Evaluation 3 is described.

First, a silicon oxynitride (SiON) film was formed to have a thickness approximately 150 nm over a glass substrate, and an indium tin oxide containing silicon (ITSO) film was formed over the silicon oxynitride film to have a thickness approximately 5 nm. Next, oxygen radical doping treatment was conducted to supply oxygen to the silicon oxynitride film through the indium tin oxide film with an ashing apparatus. Next, the indium tin oxide film was removed. Then, an aluminum nitride (AlNₓ) film was formed over the silicon oxynitride film to have a thickness of 20 nm. Then, baking was performed under conditions of a nitrogen atmosphere, a temperature of 400° C., and one hour. After the baking, the aluminum nitride film was removed.

The conditions for formation of the silicon oxynitride film, the oxygen radical doping treatment, and formation of the aluminum nitride film were similar to those in Evaluation 2.

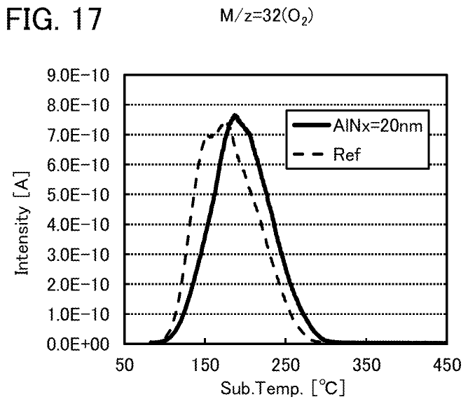

Then, the sample was subjected to TDS analysis. FIG. 17 shows TDS analysis results of the sample. In FIG. 17, the vertical axis represents the detection intensity of a mass-to-charge ratio of 32 (M/z=32) corresponding to oxygen molecules (O₂), and the horizontal axis represents the substrate temperature. Note that FIG. 17 also shows TDS analysis results of a comparative sample where the aluminum nitride film was not formed over the silicon oxynitride film, for comparison.

As shown in FIG. 17, even after the formation of the aluminum nitride film over the silicon oxynitride film supplied with oxygen and the baking, the amount of oxygen released from the silicon oxynitride film was substantially equal to that from the comparative sample. From this, it was found that the aluminum nitride film is less likely to extract oxygen in the silicon oxynitride film. In other words, it was found that oxygen supplied into the silicon oxynitride film is less likely to be extracted by the aluminum nitride film.

According to the results of Evaluation 2 and Evaluation 3, it was found that the aluminum oxide film suppresses the release of oxygen supplied to the silicon oxynitride film and less extracts the oxygen. This suggested that the formation of an aluminum nitride film over the oxide film enables the release of oxygen from the oxide film to be suppressed in heat treatment performed in a later step or the like, so that the oxygen can be kept in the oxide film.

### [Evaluation 4]

In Evaluation 4, sheet resistance of an oxide semiconductor film in baked samples in each of which an aluminum nitride film was formed over the oxide semiconductor film was evaluated.

A sample for Evaluation 4 is described. In Evaluation 4, five types of samples were fabricated.

First, three insulating films supposed to be a gate insulating film (GI) were formed over a glass substrate, and furthermore, an oxide semiconductor (OS) film was formed to have a thickness of 100 nm. Next, first baking was performed. Next, an aluminum nitride (AlNₓ) film was formed to have a thickness of 50 nm over the oxide semiconductor film. Next, second baking was performed on four out of five samples under conditions of a nitrogen atmosphere and one hour. The second baking temperatures differ depending on the samples and were 250° C., 300° C., 350° C., and 400° C. The remaining one sample was not subjected to the second baking.

As the three insulating films, a silicon nitride film containing hydrogen (SiN:H) film, a silicon nitride film, and a silicon oxynitride film were formed in this order over the glass substrate.

The oxide semiconductor film was formed by a sputtering method using an In—Ga—Zn oxide target (In:Ga:Zn=4:2:4.1) under conditions where the ratio of the O₂ flow rate to the total amount of Ar and O₂ flow rates was 30%, the power supply was 2.5 kW, the pressure was 0.6 Pa, and the substrate temperature was 200° C.

For the first baking, baking was performed under conditions of a nitrogen atmosphere, a temperature of 400° C., and one hour, and baking was further performed under conditions of a mixture atmosphere of nitrogen and oxygen, a temperature of 400° C., and one hour.

The aluminum nitride film was formed by a sputtering method under conditions where the ratio of the N₂ flow rate to the total amount of Ar and N₂ flow rates was 40%, the power supply was 5 kW, the pressure was 0.6 Pa, and the substrate temperature was 70° C.

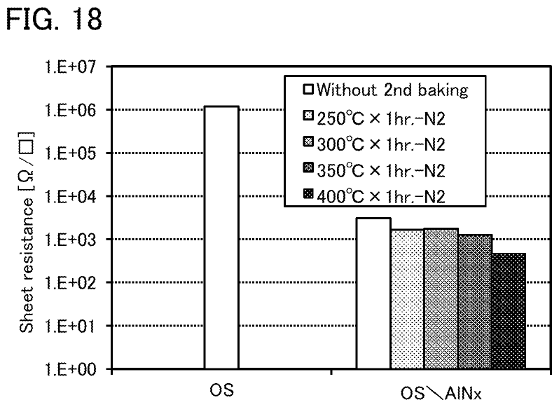

Then, sheet resistance of the oxide semiconductor film in each sample was measured. FIG. 18 shows sheet resistance of the oxide semiconductor film in each sample. In FIG. 18, the vertical axis represents sheet resistance of the oxide semiconductor film. Note that FIG. 18 also shows the sheet resistance of a comparative sample subjected to steps up to the first baking (i.e., the aluminum nitride film was not formed), for comparison.

As shown in FIG. 18, it was found that the sheet resistance of the oxide semiconductor is reduced when the aluminum nitride film is formed over the oxide semiconductor film. Moreover, it was found that a further reduction in the sheet resistance of the oxide semiconductor film is possible by performing the second baking.

### [Evaluation 5]

In Evaluation 5, the hydrogen concentration and the nitrogen concentration in an oxide semiconductor film in a baked sample where an aluminum nitride film was formed over the oxide semiconductor film were evaluated by SSDP-SIMS (Substrate Side Depth Profile Secondary Ion Mass Spectrometry) analysis (SIMS analysis conducted from a rear surface of a substrate).

The sample for Evaluation 5 is described.

First, three insulating films supposed to be a gate insulating film (GI) were formed over a glass substrate, and moreover an oxide semiconductor (OS) film was formed to have a thickness of 100 nm. Next, first baking was performed. Next, an aluminum nitride (AlNₓ) film was formed to have a thickness of 50 nm over the oxide semiconductor film. Then, second baking was performed under conditions of a nitrogen atmosphere, 350° C., and one hour.

The structure of the three insulating films, the formation conditions of the oxide semiconductor film, the conditions of the first baking, and the formation conditions of the aluminum nitride film were similar to those in Evaluation 4.

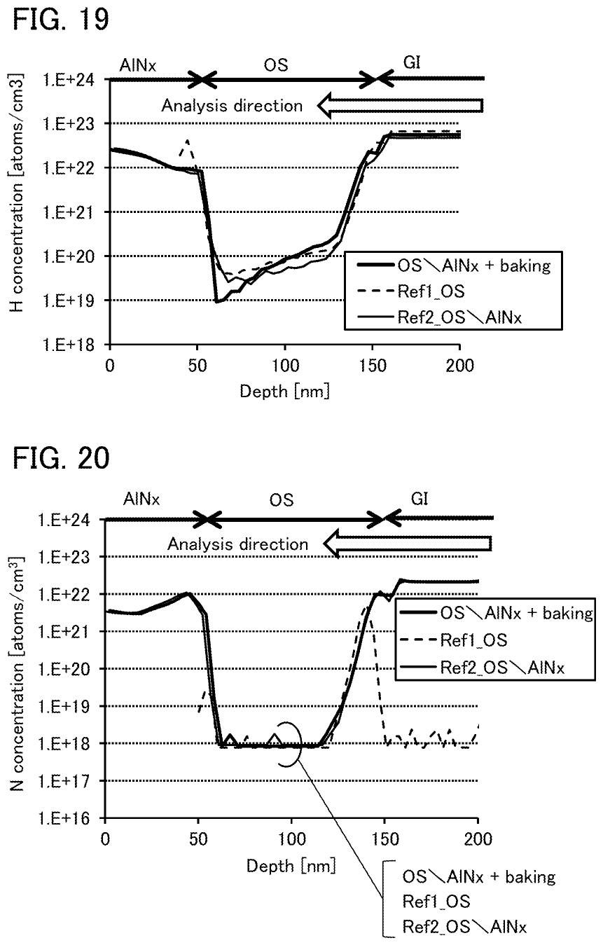

Then, the sample was subjected to SSDP-SIMS analysis. FIG. 19 shows detection results of hydrogen (H), and FIG. 20 shows detection results of nitrogen (N). In FIG. 19, the vertical axis represents the hydrogen (H) concentration, and the horizontal axis represents the depth. In FIG. 20, the vertical axis represents the nitrogen (N) concentration, and the horizontal axis represents the depth. Note that FIG. 19 and FIG. 20 also show results of a comparative sample (Ref1) where the aluminum nitride film was not formed over the oxide semiconductor film, and a comparative sample (Ref2) where the second baking was not performed after the aluminum nitride film was formed. Each sample was analyzed from the GI side as shown in FIG. 19 and FIG. 20.

As shown in FIG. 19 and FIG. 20, significant changes in the hydrogen concentration and the nitrogen concentration in the oxide semiconductor were not observed even when the aluminum nitride film was formed over the oxide semiconductor film. Furthermore, even when the second baking was performed after the aluminum nitride film was formed over the oxide semiconductor film, significant changes in the hydrogen concentration and the nitrogen concentration in the oxide semiconductor were not observed.

From the above, it was found that even when baking is performed after the aluminum nitride film is formed over the oxide semiconductor film, hydrogen and nitrogen are less likely to enter the oxide semiconductor film.

### [Evaluation 6]

In Evaluation 6, the oxygen concentration in an oxide semiconductor film in a baked sample where an aluminum nitride film was formed over the oxide semiconductor film was evaluated by SIMS analysis.

The sample for Evaluation 6 is described.

First, three insulating films supposed to be a gate insulating film (GI) were formed over a glass substrate, and an oxide semiconductor (OS) film was formed to have a thickness of 100 nm. Next, first baking was performed. Next, an aluminum nitride (AlNₓ) film was formed to have a thickness of 50 nm over the oxide semiconductor film. Then, second baking was performed under conditions of a nitrogen atmosphere, 350° C., and one hour.

The structure of the three insulating films, the conditions of the first baking, and the formation conditions of the aluminum nitride film were similar to those in Evaluation 4 and Evaluation 5.

In Evaluation 6, the oxide semiconductor film was formed using an ¹⁸O₂ gas so that the oxygen concentration was detected. Specifically, the oxide semiconductor film was formed by a sputtering method using an In-Ga—Zn oxide target (In:Ga:Zn=4:2:4.1) under conditions where the ratio of the ¹⁸O₂ flow rate to the total amount of Ar and ¹⁸O₂ flow rates was 30%, the power supply was 2.5 kW, the pressure was 0.6 Pa, and the substrate temperature was 200° C.

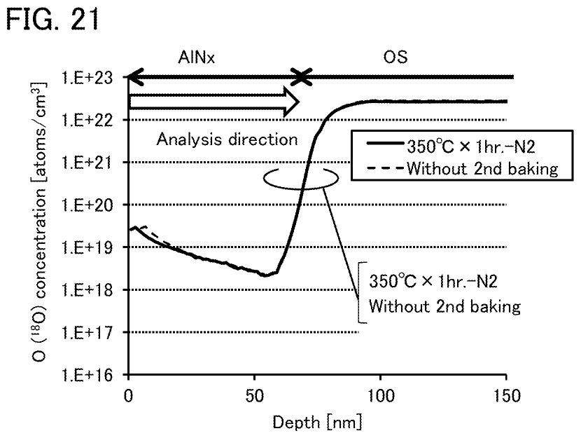

Next, the sample was subjected to SIMS analysis. FIG. 21 shows detection results of oxygen (¹⁸O). In FIG. 21, the vertical axis represents the oxygen (¹⁸O) concentration, and the horizontal axis represents the depth. Note that FIG. 21 also shows results of a comparative sample where the second baking was not performed. As shown in FIG. 21, each sample was analyzed from the AlNₓ side.

As shown in FIG. 21, even when the aluminum nitride film was formed over the oxide semiconductor film, a significant change in the oxygen (¹⁸O) concentration in the oxide semiconductor was not observed. Furthermore, even when the second baking was performed after the aluminum nitride film was formed over the oxide semiconductor film, a significant change in the oxygen (¹⁸O) concentration in the oxide semiconductor was not observed.

From the above, it was found that even when baking is performed after the aluminum nitride film is formed over the oxide semiconductor film, oxygen is less likely to be extracted from the oxide semiconductor film.

### REFERENCE NUMERALS

100: transistor, 100A to D: transistor, 102: substrate, 103: insulating layer, 104: insulating layer, 106: conductive layer, 108: semiconductor layer, 108a: semiconductor layer, 108af: metal oxide film, 108b: semiconductor layer, 108bf: metal oxide film, 108c: semiconductor layer, 108n: region, 110: insulating layer, 110f: insulating film, 112: conductive layer, 112f: conductive film, 113: dummy layer, 115: insulating layer, 116: insulating layer, 118: insulating layer, 119: insulating layer, 120a to c: conductive layer, 141a, b: opening, 142a, b: opening

1. A semiconductor device comprising:
a first insulating layer;
a second insulating layer;
a third insulating layer;
a first conductive layer; and
a semiconductor layer,
wherein the semiconductor layer is positioned over the first insulating layer,
wherein the first conductive layer is positioned over the semiconductor layer,
wherein the second insulating layer covers a side surface and a bottom surface of the first conductive layer,
wherein the third insulating layer is in contact with a top surface of the first insulating layer and a part of a top surface of the semiconductor layer and covers a side surface of the second insulating layer,
wherein the semiconductor layer contains a metal oxide,
wherein the first insulating layer and the second insulating layer each contain an oxide, and
wherein the third insulating layer contains a metal nitride.

2. A semiconductor device comprising:
a first insulating layer;
a second insulating layer;
a third insulating layer;
a fourth insulating layer;
a semiconductor layer; and
a first conductive layer,
wherein the semiconductor layer is provided over and in contact with the first insulating layer and comprises a first region and a second region,
wherein the second insulating layer is provided over the first insulating layer and the second region and comprises a first opening overlapping with the first region,
wherein the first conductive layer is positioned inside the first opening and comprises a portion overlapping with the first region,
wherein the third insulating layer is positioned inside the first opening, covers a side surface and a bottom surface of the first conductive layer, and is in contact with a top surface of the first region of the semiconductor layer,
wherein the fourth insulating layer is in contact with a top surface of the first insulating layer, a side surface of the semiconductor layer, and a top surface of the second region and comprises a portion that is inside the first opening and between the second insulating layer and the third insulating layer,
wherein the semiconductor layer contains a metal oxide,
wherein the first insulating layer and the third insulating layer each contain an oxide, and
wherein the fourth insulating layer contains a metal nitride.

3. The semiconductor device according to claim 2,
wherein the fourth insulating layer contains aluminum.

4. The semiconductor device according to claim 2, further comprising:
a fifth insulating layer covering top surfaces of the second insulating layer, the first conductive layer, and the third insulating layer,
wherein the fifth insulating layer contains oxygen and at least one of aluminum and hafnium.

5. The semiconductor device according to claim 4, further comprising:
a second conductive layer over the fifth insulating layer,
wherein the fifth insulating layer and the second insulating layer comprise a second opening reaching the second region, and
wherein the second conductive layer is in contact with the second region in the second opening.

6. The semiconductor device according to claim 2, further comprising:
a sixth insulating layer below the first insulating layer,
wherein the sixth insulating layer contains oxygen and at least one of aluminum and hafnium and oxygen.

7. The semiconductor device according to claim 6,
wherein the first insulating layer comprises a third opening reaching the sixth insulating layer, and
wherein the fourth insulating layer and the sixth insulating layer are in contact with each in the third opening.

8. The semiconductor device according to claim 6, further comprising:
a third conductive layer that is below the sixth insulating layer and overlaps with the first region.

9. A semiconductor device comprising:
an oxide semiconductor layer;
a first insulating layer over and in contact with a top surface and a side surface of the oxide semiconductor layer;
a second insulating layer over the first insulating layer, the second insulating layer comprising an opening;
a gate insulating layer over the oxide semiconductor layer;
a gate electrode over the gate insulating layer; and
a third insulating layer over and in contact with the first insulating layer, the second insulating layer, the gate insulating layer, and the gate electrode,
wherein the gate insulating layer is in contact with the first insulating layer in the opening and is not in contact with the second insulating layer.

10. The semiconductor device according to claim 9, further comprising:
a source electrode and a drain electrode over the third insulating layer,
wherein the source electrode is in contact with the oxide semiconductor layer through a first opening and the drain electrode is in contact with the oxide semiconductor layer through a second opening, and
wherein each of the first opening and the second opening is provided in the first insulating layer, the second insulating layer, and the third insulating layer.
